(19) United States
(12) Patent Application Publication
(10) Pub. No.: US 2024/0395988 A1
(43) Pub. Date: Nov. 28, 2024

(54) DISPLAY PANEL AND MANUFACTURING METHOD THEREOF, DISPALY DEVICE, AND SPLICING DISPALY DEVICE

(71) Applicants: BOE MLED Technology Co., Ltd., Beijing (CN); BOE TECHNOLOGY GROUP CO., LTD., Beijing (CN)

(72) Inventors: Lili WANG, Beijing (CN); Zhonglan ZHAO, Beijing (CN); Chao LIU, Beijing (CN); Ming ZHAI, Beijing (CN); Sha FENG, Beijing (CN); Qi QI, Beijing (CN); Jing WANG, Beijing (CN); Mingming JIA, Beijing (CN); Heling ZHU, Beijing (CN)

(73) Assignees: BOE MLED Technology Co., Ltd., Beijing (CN); BOE TECHNOLOGY GROUP CO., LTD., Beijing (CN)

(21) Appl. No.: 18/261,937

(22) PCT Filed: Jul. 15, 2022
(86) PCT No.: PCT/CN2022/106136

§ 371 Date: Jul. 18, 2023

(51) Int. Cl. H01L 33/60; H01L 25/075; H01L 33/00; H01L 33/62

(52) U.S. Cl. CPC H01L 33/60; H01L 25/0753; H01L 33/0095; H01L 33/62; H01L 2933/0058; H01L 2933/0066

(57) ABSTRACT

A display panel includes a substrate, a light-blocking layer, a plurality of connection leads and a light-emitting device layer. The substrate includes a first surface and a second surface opposite to each other, and a plurality of side surfaces connecting the first surface and the second surface. At least one of the plurality of side surfaces is a selected side surface. The light-emitting device layer is disposed on the second surface. Each of the plurality of connection leads includes a first portion located on the first surface of the substrate, a second portion located on the selected side surface of the substrate and a third portion located on the second surface of the substrate. The light-blocking layer is located between the plurality of connection leads and the substrate, and is at least located between first portions of the plurality of connection leads and the first surface of the substrate.

### CROSS-REFERENCE TO RELATED APPLICATION

This application is a national phase entry under 35 USC 371 of International Patent Application No. PCT/CN 2022/106136 filed on Jul. 15, 2022, which is incorporated herein by reference in its entirety.

### TECHNICAL FIELD

The present disclosure relates to the field of display technologies, and in particular, to a display panel and a manufacturing method thereof, a display device, and a splicing display device.

### BACKGROUND

Compared with a traditional light-emitting diode (LED), a micro light-emitting diode (Micro LED) or a mini light-emitting diode (Mini LED) is a smaller particle, i.e., has a smaller size.

### SUMMARY

In an aspect, a display panel is provided. The display panel includes a substrate, a light-blocking layer, a plurality of connection leads and a light-emitting device layer. The substrate includes a first surface and a second surface opposite to each other, and a plurality of side surfaces connecting the first surface and the second surface. At least one of the plurality of side surfaces of the substrate is a selected side surface. The light-emitting device layer is disposed on the second surface of the substrate. Each of the plurality of connection leads includes a first portion located on the first surface of the substrate, a second portion located on the selected side surface of the substrate and a third portion located on the second surface of the substrate. The light-blocking layer is located between the plurality of connection leads and the substrate, and is at least located between first portions of the plurality of connection leads and the first surface of the substrate.

In some embodiments, the light-blocking layer includes a first light-blocking layer disposed on the first surface of the substrate. The first surface of the substrate has a wiring region and a non-wiring region, and the wiring region is closer to the selected side surface of the substrate than the non-wiring region. The first portions of the plurality of connection leads are located in the wiring region. The first surface of the substrate includes a plurality of sides. The first light-blocking layer is located in the wiring region and the non-wiring region of the first surface of the substrate, and a border of an orthographic projection of the first light-blocking layer on the first surface of the substrate and a corresponding side of the first surface of the substrate have a set distance therebetween.

In some other embodiments, the light-blocking layer includes the first light-blocking layer disposed on the first surface of the substrate. The first surface of the substrate includes the wiring region and the non-wiring region, and the wiring region is closer to the selected side surface of the substrate than the non-wiring region. The first portions of the plurality of connection leads are located in the wiring region. The first surface of the substrate includes the plurality of sides. The first light-blocking layer is located in the wiring region of the first surface of the substrate, and a border of the orthographic projection of the first light-blocking layer on the first surface of the substrate and a corresponding side of the first surface of the substrate have a set distance therebetween.

In some embodiments, the light-blocking layer includes the first light-blocking layer disposed on the first surface of the substrate, and the first light-blocking layer is located in the wiring region of the first surface of the substrate. In the first portions of the plurality of connection leads, a region located between first portions of every two adjacent connection leads is a gap region. The first light-blocking layer includes a plurality of first light-blocking patterns. An orthographic projection of each first light-blocking pattern in the plurality of first light-blocking patterns on the first surface of the substrate covers at least a portion of an orthographic projection of the gap region on the first surface of the substrate that is overlapped with an orthographic projection of the light-emitting device layer on the first surface of the substrate.

In some embodiments, the light-blocking layer includes the first light-blocking layer disposed on the first surface of the substrate, and the first light-blocking layer includes the plurality of first light-blocking patterns. A dimension of each first light-blocking pattern in the plurality of first light-blocking patterns in a first direction perpendicular to an extending direction of the first light-blocking pattern is greater than or equal to a dimension of the gap region corresponding to the first light-blocking pattern in a direction perpendicular to an extending direction of the gap region.

In some embodiments, the light-blocking layer includes the first light-blocking layer disposed on the first surface of the substrate, and the first light-blocking layer is located in the wiring region of the first surface of the substrate. A border of the first light-blocking layer away from the selected side surface of the substrate is farther from the selected side surface of the substrate than borders of the plurality of connection leads away from the selected side surface of the substrate.

In some embodiments, the display panel further includes a plurality of electrodes disposed on the second surface of the substrate, and each of the plurality of electrodes is connected to a third portion of a connection lead. The light-blocking layer includes the first light-blocking layer disposed on the first surface of the substrate, and the first light-blocking layer includes the plurality of first light-blocking patterns. A dimension of the first light-blocking pattern in a first direction perpendicular to an extending direction of the first light-blocking pattern is less than a distance between two adjacent electrodes to which two adjacent connection leads corresponding to the first light-blocking pattern are respectively electrically connected.

In some embodiments, the display panel further includes the plurality of electrodes disposed on the second surface of the substrate, and each of the plurality of electrodes is connected to the third portion of the connection lead. The plurality of electrodes are arranged side by side in the first direction. A sum of a distance between first portions of the two adjacent connection leads and a dimension of a first portion of a connection lead in the two adjacent connection leads in the first direction, is equal to a sum of the distance between the two adjacent electrodes to which the two adjacent connection leads are respectively electrically connected and a dimension of an electrode in the two adjacent electrodes in the first direction.

In some embodiments, the display panel further includes the plurality of electrodes disposed on the second surface of the substrate, and each of the plurality of electrodes is connected to the third portion of the connection lead. The plurality of electrodes are arranged side by side in the first direction. The two adjacent electrodes are respectively electrically connected to the two adjacent connection leads. A difference between the distance between the two adjacent electrodes and the distance between the first portions of the two adjacent connection leads is greater than a difference between the dimension of the first portion of the connection lead in the two adjacent connection leads in the first direction and a dimension of an electrode electrically connected to this connection lead in the first direction.

In some embodiments, the light-blocking layer further includes a second light-blocking layer disposed on the second surface of the substrate. The second surface of the substrate has a display region and a peripheral region disposed on a side of the display region. An orthographic projection of the second light-blocking layer on the second surface of the substrate covers at least a portion, overlapped with the display region, of a region of the second surface of the substrate corresponding to the wiring region. Moreover, a border of the orthographic projection of the second light-blocking layer on the second surface of the substrate and a corresponding side of the second surface of the substrate have a set distance therebetween.

In some embodiments, the light-blocking layer includes the first light-blocking layer disposed on the first surface of the substrate, and the second surface of the substrate includes the display region and the peripheral region disposed on the side of the display region. A distance between a border, proximate to the selected side surface, of the orthographic projection of the first light-blocking layer on the first surface of the substrate and the selected side surface of the substrate is less than a distance between a border of the display region proximate to the selected side surface and the selected side surface of the substrate.

In some embodiments, the first surface of the substrate includes the plurality of sides, and in the plurality of sides included in the first surface of the substrate, a side proximate to the selected side surface of the substrate is a first selected side. A distance between a border, proximate to a side in the plurality of sides of the first surface except the first selected side, of the orthographic projection of the first light-blocking layer on the first surface of the substrate and the side in the plurality of sides included the first surface of the substrate except the first selected side, is less than a distance between a border, proximate to the first selected side, of the orthographic projection of the first light-blocking layer on the first surface of the substrate and the first selected side.

In some other embodiments, the light-blocking layer further includes a second light-blocking layer disposed on the second surface of the substrate. The second surface of the substrate includes a plurality of sides, and in the plurality of sides included in the second surface of the substrate, a side proximate to the selected side surface of the substrate is a second selected side. A distance between a border, proximate to a side in the plurality of sides of the second surface except the second selected side, of an orthographic projection of the second light-blocking layer on the second surface of the substrate and the side in the plurality of sides included the second surface of the substrate except the second selected side, is less than a distance between a border, proximate to the second selected side, of the orthographic projection of the second light-blocking layer on the second surface of the substrate and the second selected side.

In yet other embodiments, the light-blocking layer includes the first light-blocking layer disposed on the first surface of the substrate and the second light-blocking layer disposed on the second surface of the substrate. The first surface of the substrate includes the plurality of sides, and in the plurality of sides included in the first surface of the substrate, the side proximate to the selected side surface of the substrate is the first selected side. The distance between the border, proximate to the side in the plurality of sides of the first surface except the first selected side, of the orthographic projection of the first light-blocking layer on the first surface of the substrate and the side in the plurality of sides included the first surface of the substrate except the first selected side, is less than the distance between the border, proximate to the first selected side, of the orthographic projection of the first light-blocking layer on the first surface of the substrate and the first selected side. The second surface of the substrate includes the plurality of sides, and in the plurality of sides included in the second surface of the substrate, the side proximate to the selected side surface of the substrate is the second selected side. The distance between the border, proximate to the side in the plurality of sides of the second surface except the second selected side, of the orthographic projection of the second light-blocking layer on the second surface of the substrate and the side in the plurality of sides included the second surface of the substrate except the second selected side, is less than the distance between the border, proximate to the second selected side, of the orthographic projection of the second light-blocking layer on the second surface of the substrate and the second selected side.

In some embodiments, the light-blocking layer includes the first light-blocking layer disposed on the first surface of the substrate. The first surface of the substrate includes the plurality of sides, and in the plurality of sides included in the first surface of the substrate, the side proximate to the selected side surface of the substrate is the first selected side. The distance between the border, proximate to the side in the plurality of sides of the first surface except the first selected side, of the orthographic projection of the first light-blocking layer on the first surface of the substrate and the side in the plurality of sides included in the first surface of the substrate except the first selected side is greater than or equal to 30 μm.

In some embodiments, a dimension of the light-blocking layer in a direction perpendicular to the substrate is greater than or equal to 0.3 μm.

In some embodiments, the light-blocking layer is made of an insulating light-shielding material.

In some embodiments, a reflectivity of the light-blocking layer to laser is greater than a reflectivity of the plurality of connection leads to the laser.

In some embodiments, the light-blocking layer is made of any one of silicon nitride, monocrystalline silicon, silicon oxide, fluoride and ink.

In some embodiments, the display panel further includes a protective layer disposed on a side of the plurality of connection leads away from the substrate.

In another aspect, a display device is provided. The display device includes the display panel in any one of the above embodiments.

In yet another aspect, a splicing display device is provided. The splicing display device includes display devices in any one of the above embodiments.

In yet another aspect, a manufacturing method of a display panel is provided. The manufacturing method of the display panel includes following steps.

An initial substrate is provided. The initial substrate includes a first surface and a second surface opposite to each other, and the initial substrate has a plurality of substrate partitions arranged in an array.

A plurality of light-blocking layers are formed on the initial substrate. Forming the plurality of light-blocking layers on the initial substrate, includes: at least forming a plurality of first light-blocking layers on the first surface of the initial substrate. Two adjacent first light-blocking layers have an interval therebetween, and each substrate partition includes at least one first light-blocking layer.

A plurality of driving circuit layers arranged in an array are formed on the second surface of the initial substrate. Each substrate partition includes a driving circuit layer.

The initial substrate is cut to obtain a plurality of substrates. Each substrate is provided with a driving circuit layer and at least one first light-blocking layer. The substrate includes a first surface and a second surface opposite to each other, and a plurality of side surfaces connecting the first surface and the second surface. At least one of the plurality of side surfaces is a selected side surface, and the first surface of the substrate and the first surface of the initial substrate are in a same plane.

A plurality of connection leads are formed on a side of the at least one first light-blocking layer away from the substrate. Each of the plurality of connection leads includes a first portion located on the first surface of the substrate, a second portion located on the selected side surface of the substrate and a third portion located on the second surface of the substrate. The at least one first light-blocking layer is located between first portions of the plurality of connection leads and the substrate.

A light-emitting device layer is formed on a side of the driving circuit layer away from the substrate.

In some embodiments, forming the plurality of light-blocking layers on the initial substrate, further includes a following step.

A plurality of second light-blocking layers are formed on the second surface of the initial substrate. Two adjacent second light-blocking layers have an interval therebetween, and each substrate partition includes a second light-blocking layer.

The plurality of driving circuit layers arranged in the array are formed on the second surface of the initial substrate, includes: forming the plurality of driving circuit layers arranged in the array on a side of the plurality of second light-blocking layers away from the initial substrate. Each driving circuit layer is disposed on a second light-blocking layer.

The initial substrate is cut to obtain the plurality of substrates, so that each substrate is further provided with a second light-blocking layer.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, and are not limitations on an actual size of a product, an actual process of a method, and an actual timing of a signal involved in the embodiments of the present disclosure.

FIG. 1 is a sectional view of a display panel;

FIG. 2A is a front view of a display panel, in accordance with some embodiments;

FIG. 2B is a front view of a display panel, in accordance with some other embodiments;

FIG. 3A is a back view of a display panel, in accordance with some embodiments;

FIG. 3B is a back view of a display panel, in accordance with some other embodiments;

FIG. 4 is a sectional view of a display panel, in accordance with some embodiments;

FIG. 5 is a sectional view of a display panel, in accordance with some other embodiments;

FIG. 6 is a sectional view of a display panel, in accordance with yet other embodiments;

FIG. 7 is a sectional view of a display panel, in accordance with yet other embodiments;

FIG. 8 is a sectional view of a display panel, in accordance with yet other embodiments;

FIG. 9 is a structural diagram of a first light-blocking layer, in accordance with some embodiments;

FIG. 10 is a structural diagram of a first light-blocking layer, in accordance with some other embodiments;

FIG. 11A is a structural diagram of a first light-blocking layer, in accordance with some embodiments;

FIG. 11B is a structural diagram of a first light-blocking layer, in accordance with some other embodiments;

FIG. 12A is a structural diagram of a first light-blocking layer, in accordance with yet other embodiments;

FIG. 12B is a structural diagram of a first light-blocking layer, in accordance with yet other embodiments;

FIG. 13A is a structural diagram of a second light-blocking layer, in accordance with some embodiments;

FIG. 13B is a structural diagram of a second light-blocking layer, in accordance with some other embodiments;

FIG. 14 is a structural diagram of a second light-blocking layer, in accordance with yet other embodiments;

FIG. 15 is an enlarged front view of the G1 region of the display panel shown in FIG. 2A;

FIG. 16 is another enlarged front view of the G1 region of the display panel shown in FIG. 2A;

FIG. 17 is an enlarged back view of the G1 region of the display panel shown in FIG. 2A;

FIG. 18 is a structural diagram of electrodes and connection leads, in accordance with some embodiments;

FIG. 19 is a structural diagram of connection leads and first light-blocking patterns, in accordance with some embodiments;

FIG. 20A is a front view of film layers of a display panel, in accordance with some embodiments;

FIG. 20B is front view of a display panel, in accordance with some embodiments;

FIG. 20C is a sectional view of a display panel, in accordance with some embodiments;

FIG. 21 is a structural diagram of a protective layer of a display panel, in accordance with some embodiments;

FIG. 22 is a front view of a display device, in accordance with some embodiments;

FIG. 23 is a front view of a splicing display device, in accordance with some embodiments;

FIG. 24 is a front view of a splicing display device, in accordance with some other embodiments;

FIG. 25A is a flow diagram of a manufacturing method of a display panel, in accordance with some embodiments;

FIG. 25B is a flow diagram of a manufacturing method of a display panel, in accordance with some other embodiments;

FIG. 26A is a structural diagram corresponding to S2 in FIG. 25A or FIG. 25B;

FIG. 26B is a structural diagram corresponding to S2 in FIG. 25A or FIG. 25B;

FIG. 27A is a structural diagram corresponding to S3 in FIG. 25A; and

FIG. 27B is a structural diagram corresponding to S3 in FIG. 25B.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “an example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are only used for descriptive purposes, and are not to be construed as indicating or implying relative importance or implicitly indicating the number of indicated technical features. Thus, a feature defined with “first” or “second” may explicitly or implicitly include one or more of the features. In the description of the embodiments of the present disclosure, the term “a plurality of/the plurality of” means two or more unless otherwise specified.

In the description of some embodiments, the term “coupled” and “connected” and derivatives thereof may be used. For example, the term “connected” may be used in the description of some embodiments to indicate that two or more components are in direct physical or electrical contact with each other. The embodiments disclosed herein are not necessarily limited to the contents herein.

The phrase “A and/or B” includes following three combinations: only A, only B, and a combination of A and B.

The use of the phase “applicable to” or “configured to” herein means an open and inclusive expression, which does not exclude devices that are applicable to or configured to perform additional tasks or steps.

As used herein, the term “about,” “substantially” or “approximately” includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

As used herein, the term such as “parallel,” “perpendicular” or “equal” includes a stated condition and condition(s) similar to the stated condition. The similar condition(s) are within an acceptable range of deviation as determined by a person of ordinary skill in the art, considering measurement in question and errors associated with measurement of a particular quantity (i.e., limitations of a measurement system). For example, the term “parallel” includes “absolutely parallel” and “approximately parallel”, and for the phrase “approximately parallel”, an acceptable range of deviation may be, for example, within 5°. The term “perpendicular” includes “absolutely perpendicular” and “approximately perpendicular”, and for the phrase “approximately perpendicular”, an acceptable range of deviation may also be, for example, within 5°. The term “equal” includes “absolutely equal” and “approximately equal”, and for the phrase “approximately equal”, an acceptable range of deviation may be that, for example, a difference between two that are equal to each other is less than or equal to 5% of any one of the two.

It will be understood that when a layer or element is described as being on another layer or substrate, the layer or element may be directly on the another layer or substrate, or intermediate layer(s) may exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing techniques and/or tolerances may be envisaged. Therefore, the exemplary embodiments should not be construed to be limited to the shapes of regions shown herein, but to include deviations in shape due to, for example, manufacturing. Therefore, the regions shown in the accompanying drawings are schematic in nature, and their shapes are not intended to show actual shapes of the regions in a device, and are not intended to limit the scope of the exemplary embodiments.

In order to improve product reliability and reduce transportation costs and maintenance costs, a large-size display device may be assembled by splicing a plurality of small-size display devices.

In order to avoid fragmentation of a display picture caused by splicing, it is necessary to reduce a bezel size of a single small-size display device to reduce a width of a splicing seam. The small-size display device includes a display panel. For example, a wiring located on a display surface of the display panel may be connected to a circuit board (e.g., a flexible printed circuit) disposed on a non-display surface of the display panel through a side wiring, so that when the plurality of small-size display devices are spliced to form the large-size display device with a larger size, a distance between adjacent small-size display devices may be smaller, thereby improving the display quality.

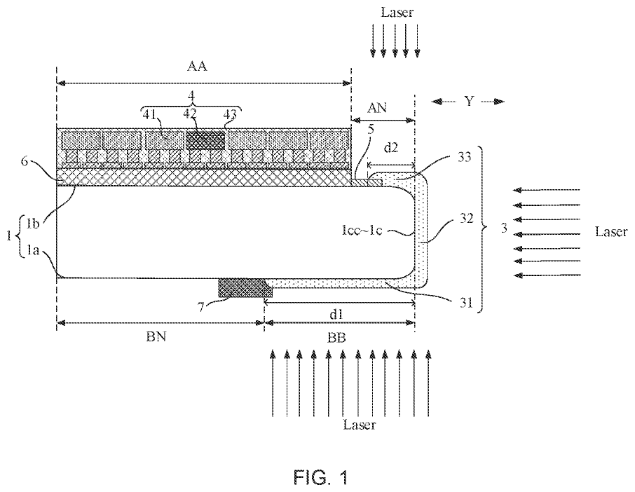

As shown in FIG. 1, the display panel may include a substrate 1 and a plurality of connection leads 3. The substrate 1 includes a first surface 1a and a second surface 1b opposite to each other, and a plurality of side surfaces 1c connecting the first surface 1a and the second surface 1b. Each of at least one of the plurality of side surfaces 1c of the substrate 1 is a selected side surface 1cc. Each of the plurality of connection leads 3 includes a first portion 31 located on the first surface 1a of the substrate 1, a second portion 32 located on the selected side surface 1cc of the substrate 1, and a third portion 33 located on the second surface 1b of the substrate 1.

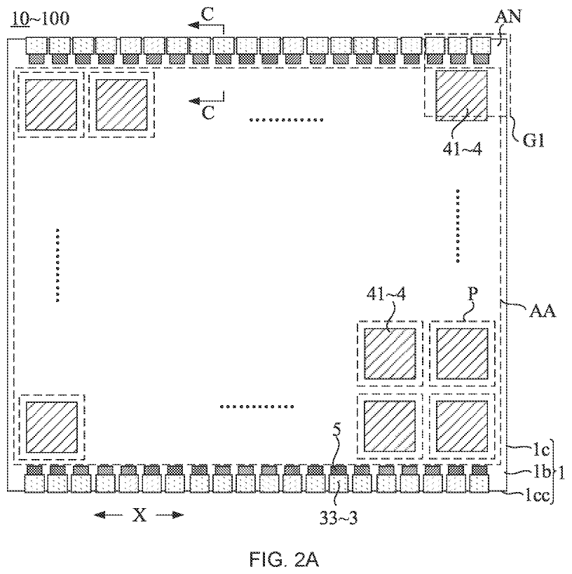

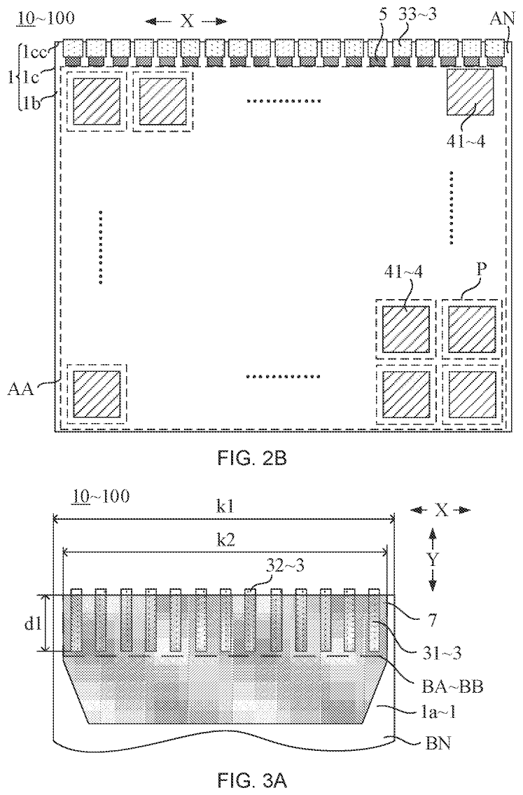

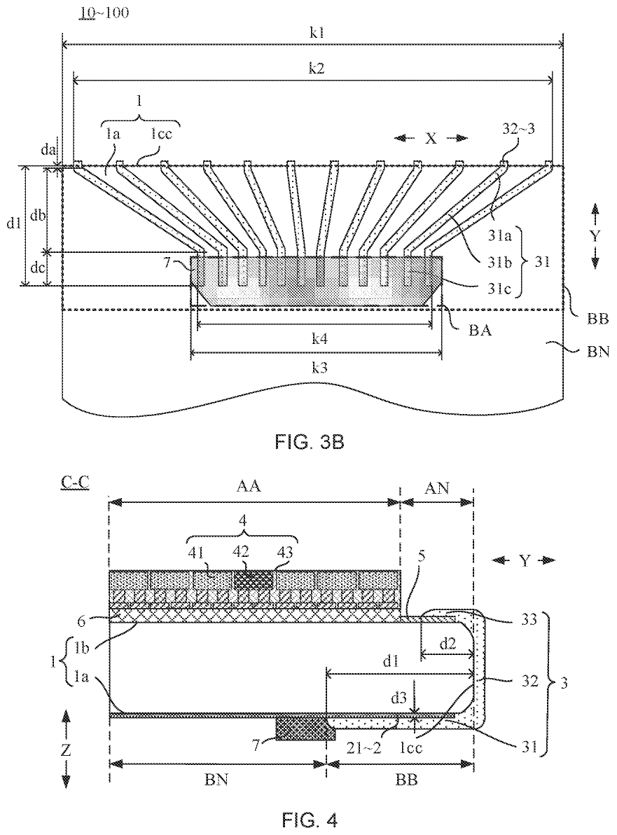

The first surface 1a of the substrate is a back of the display panel, and the second surface 1b of the substrate is a front of the display panel. As shown in FIGS. 2A and 2B, the second surface 1b of the substrate 1 has a display region AA and peripheral region(s) AN. The display region AA is provided with a driving circuit layer 6 and other film layer structures therein, and is further provided with a plurality of light-emitting devices 41 therein. Third portions 33 of the plurality of connection leads are located in the peripheral region(s) AN. As shown in FIGS. 3A and 3B, the first surface 1a of the substrate 1 has wiring region(s) BB, and first portions 31 of the plurality of connection leads are located in the wiring region(s) BB.

The first portions 31 of the plurality of connection leads 3 located on the first surface 1a are configured to be connected to a flexible printed circuit located on the first surface 1a. For example, an end of the first portion 31 away from the selected side surface 1cc is used as a bonding electrode connected to the flexible printed circuit 7. That is, it is necessary to reserve a large space for wirings on the back of the display panel for external wiring bonding. Therefore, in a direction perpendicular to the selected side surface, a line length of the first portion 31 of the connection lead 3 is greater than a line length of the third portion 33 of the connection lead. That is, the first portions of the plurality of connection leads 3 located on the first surface 1a of the substrate 1 have a length of d1, and the third portions 33 of the plurality of connection leads located on the second surface 1b of the substrate 1 have a length of d2, and d1 is greater than d2. An orthographic projection of the first portion 31 of the connection lead 3 on the second surface extends into the display region AA.

For the lengths d1 of the first portions of the plurality of connection leads 3 located on the first surface 1a of the substrate 1, there are following cases.

In some embodiments, the first portion 31 is linear. For example, as shown in FIG. 3A, the first portion 31 extends in a Y direction. Then, the length d1 of the first portion 31 is a dimension of the first portion 31 in an extending direction Y thereof.

In some other embodiments, the first portion 31 is curved and bent. The first portion 31 includes a plurality of portions with different extending directions that are connected end to end in sequence. For example, as shown in FIG. 3B, the first portion 31 of each connection lead 3 includes a first sub-line 31a, a second sub-line 31b and a third sub-line 31c. Extending directions of the first sub-line 31a, the second sub-line 31b and the third sub-line 31c are different, but the first portion 31 extends in the Y direction as a whole. Then, the length d1 of the first portion 31 that is curved and bent is a dimension, in the extending direction Y of the first portion 31 as a whole, of an orthographic projection of the first portion 31 on the substrate 1.

In some examples, a manufacturing process of the plurality of connection leads 3 is as follows. Connection metal layer(s), each of which is a whole layer, are respectively formed on the at least one side surface 1c of the substrate 1. For example, the connection metal layer(s) are formed by a three-dimensional sputtering coating process. The connection metal layer is located on the first surface 1a of the substrate 1, the side surface 1c of the substrate 1, and the second surface 1b of the substrate 1. Then, the connection metal layer(s) are patterned by laser process trimming to form the plurality of independent connection leads 3.

It will be understood that each connection lead 3 includes the first portion 31 located on the first surface 1a of the substrate 1, the second portion 32 located on the selected side surface 1cc of the substrate 1, and the third portion 33 located on the second surface 1b of the substrate 1, and the line length of the first portion 31 of the connection lead 3 is greater than the line length of the third portion 33 of the connection lead, so that an area of a portion of the connection metal layer located on the first surface 1a of the substrate 1 is larger than an area of a portion of the connection metal layer located on the second surface 1b of the substrate 1. In this way, in an actual laser process, a longer line length needs to be obtained by laser etching on the first surface 1a of the substrate 1. In the etching process to obtain the first portions 31 of the connection leads 3, laser may pass through the substrate 1, and may be incident into the display region AA of the second surface 1b. Referring to FIG. 1, the laser is irradiated to the substrate 1 in directions of the laser shown in the figure. Since the orthographic projection of the first portion 31 of the connection lead 3 on the substrate 1 is overlapped with the display region AA, part of energy of the laser passes through the substrate 1 to reach the display region AA, and causes damage to film layers and devices in this region, which results in reliability problems such as localized corrosion.

In some embodiments, the driving circuit layer includes thin film transistors. When the laser is used for etching to obtain the first portions 31 of the connection leads 3, active layers of the thin film transistors in the front driving circuit layer are irradiated by the laser, so that characteristics of the thin film transistors are changed. For example, a threshold current for turning off the thin film transistor is increased, thereby affecting the display effect. The above manufacturing processes, such as the sputtering coating process and the laser process, are only described as examples, and are not intended to limit an actual production process.

A display panel, a display device and a splicing display device provided in the present disclosure will be described below.

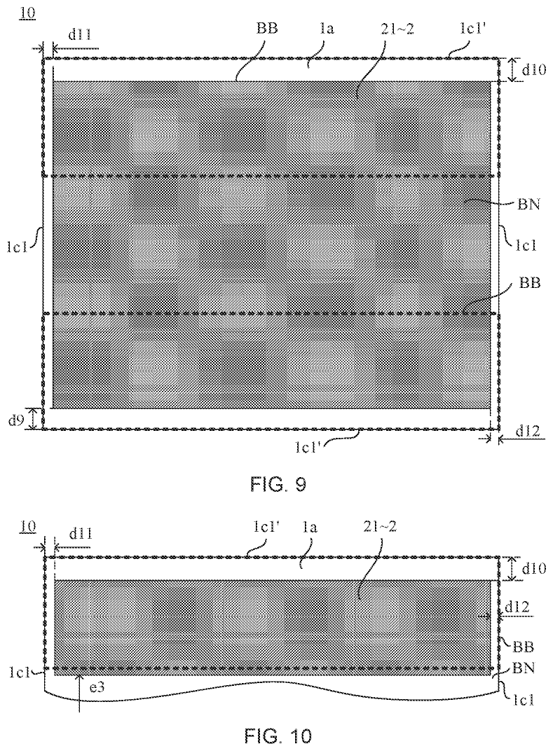

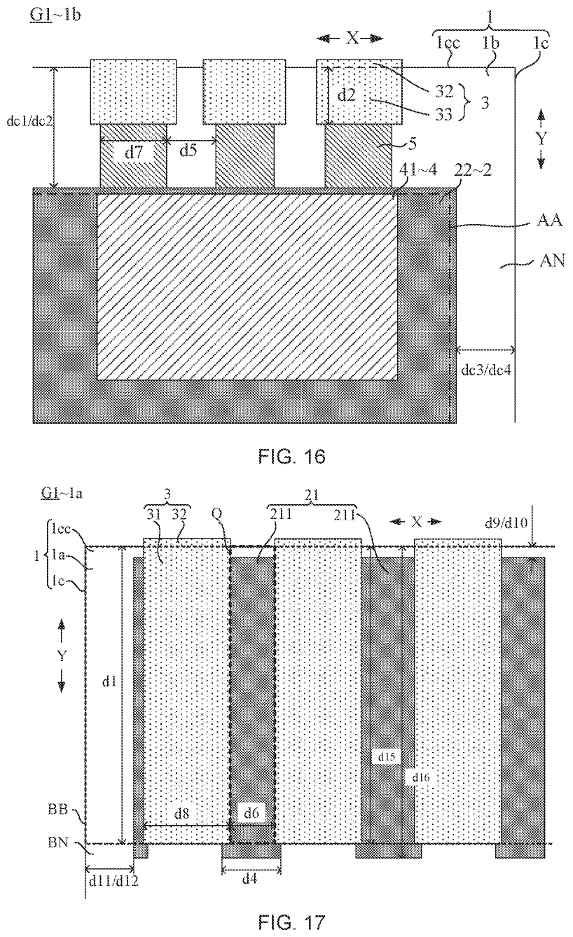

In the present disclosure, FIGS. 2A, 2B, 3A and 3B are plan views of the display panel 10, FIGS. 4, 5, 6 and 7 are sectional views of the display panel 10 taken along the CC section line in FIG. 2A, FIGS. 15 and 16 are enlarged front views of the G1 region of the display panel shown in FIG. 2A, and FIG. 17 is an enlarged back view of the G1 region of the display panel shown in FIG. 2A. In order to facilitate a clear description of structural details of a light-blocking layer 2, connection leads 3, a light-emitting device layer 4 and electrodes 5 of the display panel in FIGS. 2A, 3A and 3B are removed to obtain structure diagrams respectively shown in FIGS. 9, 10, 13A, 13B and 14 and each include only a substrate 1 and the light-blocking layer 2.

Hereinafter, a side of the display panel 10 provided with light-emitting devices 41, i.e., a side of the display panel 10 where a second surface 1b is located, is referred to as a front of the display panel 10, and accordingly, a side of the display panel 10 where a first surface 1a is located is referred to as a back of the display panel 10.

Some embodiments of the present disclosure provide the display panel 10. As shown in FIGS. 4 to 8, the display panel 10 includes the substrate 1, the plurality of connection leads 3, the light-emitting device layer 4 and a driving circuit layer 6, and further includes the light-blocking layer 2. Structures of the substrate 1 and the plurality of connection leads 3 refer to the description of FIG. 1.

For example, as shown in FIGS. 2A and 2B, the first surface and the second surface of the substrate 1 are, for example, rectangular. The substrate 1 includes four side surfaces 1c.

For example, the substrate 1 is made of, for example, a rigid material such as glass, quartz, or plastic.

The driving circuit layer 6 is disposed on the second surface 1b of the substrate 1, and is located in the display region AA. The light-emitting device layer 4 is disposed on a side of the driving circuit layer 6 away from the substrate 1. The light-emitting device layer 4 includes a plurality of light-emitting devices 41. The driving circuit layer 6 includes signal wirings connected to the light-emitting devices 41, and the signal wirings are configured to transmit signals to the light-emitting devices 41 to drive the plurality of light-emitting devices 41 in the light-emitting device layer 4 to emit light. The above laser damage to the film layers on the front of the display panel includes damage to the driving circuit layer 6 and the light-emitting device layer 4.

The light-blocking layer 2 is located between the plurality of connection leads 3 and the substrate 1, and is at least located between the first portions 31 of the plurality of connection leads 3 and the substrate 1. That is, the light-blocking layer 2 is disposed on a surface of the substrate 1, and is closer to the substrate 1 than the plurality of connection leads, and is at least disposed on the first surface 1a of the substrate 1. Moreover, the light-blocking layer 2 is closer to the substrate 1 than the first portions 31 of the plurality of connection leads 3.

The light-blocking layer 2 is configured to block the laser to prevent the laser from damaging the film layers on the front of the display panel 10. For example, the light-blocking layer is capable of reflecting or absorbing the laser.

The light-blocking layer 2 is at least disposed between the first portions 31 of the plurality of connection leads 3 and the substrate 1, so that in a manufacturing process of the plurality of connection leads 3 of the display panel 10, when the laser is used for etching the connection metal layer(s), after the connection metal layer(s) are etched by laser travelling to the first surface 1a of the substrate 1 to form the first portions 31 of the plurality of connection leads, the laser is blocked by the light-blocking layer 2. For example, the light-blocking layer 2 is capable of reflecting or absorbing the laser to prevent photons from entering the front of the display panel 10, so that residual energy of the laser is prevented from generating thermal effects or even damage to the film layers (e.g., the driving circuit layer 6 shown in FIGS. 4 to 8) on the front of the display panel 10, thereby ensuring a structural integrity of the display panel to improve a product yield.

In some examples, as shown in FIGS. 4 to 8, the light-blocking layer 2 includes first light-blocking layer(s) 21 disposed on the first surface 1a of the substrate 1, and/or the light-blocking layer 2 includes second light-blocking layer(s) 22 disposed on the second surface 1b of the substrate 1.

In a case where the driving circuit layer includes thin film transistors, when etching is performed to obtain the first portions 31 of the connection leads 3 located in the wiring region(s) BB, active layers of the thin film transistors in the front driving circuit layer are irradiated by the laser, so that characteristics of the thin film transistors are changed. For example, a threshold current for turning off the thin film transistor is increased, thereby affecting the display effect.

The second light-blocking layer(s) 22 may be disposed at a position corresponding to orthographic projections, on the substrate 1, of the active layers of the thin film transistors in the driving circuit layer. In this way, after passing through the substrate 1, the laser travelling to the first surface of the substrate may be blocked by the second light-blocking layer(s) 22, so that the laser is prevented from affecting the film layers (e.g., the active layers of the thin film transistors in the driving circuit layer) on the front of the display panel 10, thereby ensuring the display effect of the display panel 10.

It will be noted that limitations on the distribution position and the shape of the light-blocking layer in the present disclosure only need to ensure that the light-blocking layer is distributed at a position of laser etching, and is capable of preventing the laser from passing through the substrate 1 to reach the front film layers.

Following descriptions of a thickness and a material of the light-blocking layer 2 are applicable to both the first light-blocking layer 21 and the second light-blocking layer 22.

Hereinafter, a dimension of the light-blocking layer 2 in a direction Z perpendicular to the substrate 1 is referred to as the thickness of the light-blocking layer 2.

In some examples, the light-blocking layer 2 is designed to be a plane layer, and thicknesses of the light-blocking layer 2 at various positions are the same or substantially the same.

In some other examples, the light-blocking layer 2 is designed to be a gradient layer, and a thickness of a portion of the light-blocking layer 2 located in a region corresponding to the display region AA is greater than a thickness of the rest of the light-blocking layer 2.

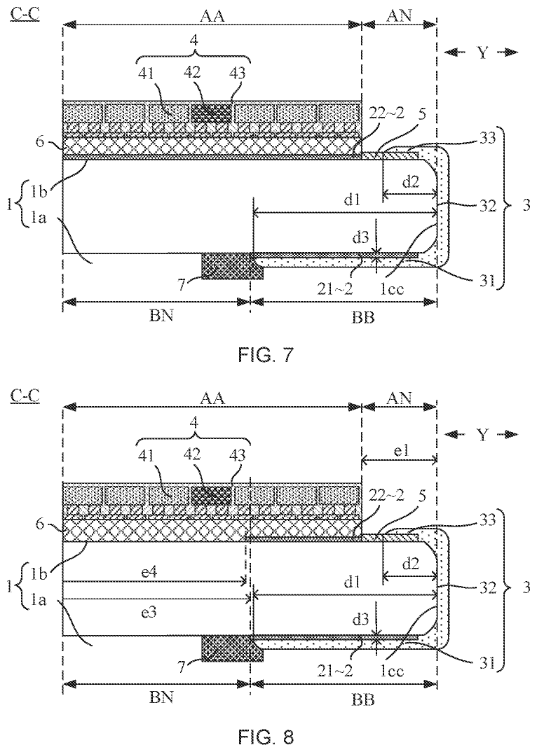

For example, as shown in FIGS. 6 and 7, the light-blocking layer 2 covers, for example, the entire first surface 1a and/or the entire second surface 1b of the substrate 1. That is, an orthographic projection of the light-blocking layer 2 on the second surface 1b of the substrate 1 is overlapped or substantially overlapped with the second surface 1b of the substrate 1, and the region corresponding to the display region AA is a region covered by an orthographic projection of a region covered by the display region AA on the second surface 1b of the substrate 1. The portion of the light-blocking layer 2 located in the region corresponding to the display region AA is referred to as a first portion of the light-blocking layer 2, and a portion of the light-blocking layer 2 except the portion located in the region corresponding to the display region AA is referred to as a second portion of the light-blocking layer 2. Then, a thickness of the first portion of the light-blocking layer 2 is greater than a thickness of the second portion of the light-blocking layer 2.

In some embodiments, the light-blocking layer 2 includes the first light-blocking layer(s) 21 disposed on the first surface 1a of the substrate 1 and the second light-blocking layer(s) 22 disposed on the second surface 1b of the substrate 1. Then, the orthographic projection of the light-blocking layer 2 on the second surface 1b of the substrate 1 refers to an orthographic projection of the first light-blocking layer(s) 21 on the second surface 1b of the substrate 1 and an orthographic projection of the second light-blocking layer(s) 22 on the second surface 1b of the substrate 1. Thicknesses of the first light-blocking layer 21 and the second light-blocking layer 22 satisfy the above description.

In some other embodiments, the light-blocking layer 2 includes only the first light-blocking layer(s) 21 disposed on the first surface 1a of the substrate 1 or the second light-blocking layer(s) 22 disposed on the second surface 1b of the substrate 1. Then, the orthographic projection of the light-blocking layer 2 on the second surface 1b of the substrate 1 refers to the orthographic projection of the first light-blocking layer(s) 21 on the second surface 1b of the substrate 1 or the orthographic projection of the second light-blocking layer(s) 22 on the second surface 1b of the substrate 1.

Furthermore, a thickness of a portion where the first portion of the light-blocking layer 2 is connected to the second portion of the light-blocking layer 2 is gradually changed. In a region of the portion where the first portion of the light-blocking layer 2 is connected to the second portion of the light-blocking layer 2, the closer to the first portion of the light-blocking layer 2, the greater the thickness of the light-blocking layer 2.

For example, as shown in FIGS. 4 to 8, the dimension d3 of the light-blocking layer 2 in the direction Z perpendicular to the substrate 1 is greater than or equal to 0.3 μm. The dimension d3 of the light-blocking layer 2 in the direction perpendicular to the substrate 1 is, for example, 0.3 μm, 0.4 μm or 0.5 μm.

Under a premise of not affecting a stress of the light-blocking layer 2, the thickness of the light-blocking layer 2 may be appropriately increased. On one hand, due to the increased thickness of the light-blocking layer 2, the light-blocking layer 2 is capable of better blocking the laser penetration, so that an extinction ability of the light-blocking layer 2 is enhanced to weaken the laser. On another hand, the light-blocking layer 2 may further be used as a sacrificial layer. In this way, even if the light-blocking layer 2 is subjected to a mechanical damage or a chemical damage due to bumps or other reasons in the laser etching process or other processes, which results in a reduction in thickness of a damaged portion of the light-blocking layer 2, the light-blocking layer 2 may still maintain a certain thickness, and is still capable of preventing the laser from entering the display region AA on the front of the display panel 10, thereby preventing the film layers on the front of the display panel 10 from being damaged by the laser.

In some embodiments, a reflectivity of the light-blocking layer to the laser is greater than a reflectivity of the plurality of connection leads to the laser.

The reflectivity of the plurality of connection leads to the laser herein refers to a reflectivity of a material of the plurality of connection leads to the laser. When the plurality of connection leads are manufactured, after a portion between two adjacent connection leads is etched, the laser meets the light-blocking layer with a higher reflectivity to the laser. It will be understood that the absorption of the laser is reduced, thereby weakening the laser. Furthermore, the laser is prevented from passing through the substrate to be irradiated onto the film layer structures in the display region.

For example, the foregoing laser is an ultraviolet laser, and a wavelength band of the ultraviolet laser is, for example, 266 nm, 308 nm or 355 nm. An absorption rate of the light-blocking layer to the laser is greater than 1.2%.

The laser herein is a laser used when the plurality of connection leads are manufactured by the laser etching.

The light-blocking layer 2 has good optical properties. That is, the reflectivity of the light-blocking layer 2 is not less than a reflectivity of the connection metal layer(s) for manufacturing the plurality of connection leads 3 included in the display panel 10. In this way, in the process of manufacturing the plurality of connection leads 3, after the connection metal layer(s) are etched, the laser meets the light-blocking layer 2 with a higher reflectivity, and the absorption of the laser is reduced, so that the laser is weakened, thereby ensuring that the laser emitted from the back of the display panel 10 does not pass through the light-blocking layer 2 to travel to the front of the display panel 10, and thus does not cause damage to the film layers (e.g., the driving circuit layer 6 located in the display region AA) on the front of the display panel 10.

In some embodiments, the light-blocking layer 2 is made of an insulating light-shielding material.

The light-blocking layer cannot affect the drive of the display panel 10 under a premise of blocking the laser. For example, the light-blocking layer is connected to (in direct contact or electrical connection with) other structures of the display panel such as the film layers on the front of the display panel, which does not result in short circuit and signal interference problems of the display panel 10.

For example, the light-blocking layer 2 is made of any one of silicon nitride, monocrystalline silicon, silicon oxide, fluoride and ink.

The light-shielding performance of the light-blocking layer 2 is used for blocking the laser, so that the laser is prevented from damaging the film layers (e.g., the driving circuit layer 6) on the front of the display panel 10 during the processing of the display panel 10. Moreover, since the light-blocking layer 2 is made of an insulating material, in a case where the display panel 10 is further provided with conductive structures such as other connection leads, the normal operation of the display panel 10 is prevented from being affected caused by a short circuit of wirings on the back due to a fact that the light-blocking layer 2 is connected to conductive structures such as connection leads on the back of the display panel 10.

In some examples, the light-blocking layer 2 is designed to be a single layer. The light-blocking layer 2 is made of, for example, any one of silicon nitride, monocrystalline silicon, silicon oxide, fluoride and ink.

In some other examples, the light-blocking layer 2 is designed to be stacked layers. For example, the light-blocking layer 2 includes a silicon nitride layer and a silicon oxide layer arranged in sequence from a side of the substrate 1.

A specific location of the light-blocking layer 2, and the shape and the size of the light-blocking layer 2 will be described below.

In some examples, the light-blocking layer 2 is arranged next to the substrate 1. That is, the first light-blocking layer(s) 21 are arranged next to the first surface 1a of the substrate 1, and/or the second light-blocking layer(s) 22 are arranged next to the second surface 1b of the substrate 1.

In some other examples, other film layer structure(s) are included between the light-blocking layer 2 and the substrate 1. For example, a first buffer layer is further included between the first surface 1a of the substrate 1 and the first light-blocking layer 21, and/or a second buffer layer is further included between the second surface 1b of the substrate 1 and the second light-blocking layer 22.

It will be noted that the film layer structure(s) between the light-blocking layer 2 and the substrate 1 herein are not used for signal transmission, and do not participate in circuit connection. Therefore, even if the film layer structure(s) are damaged by the laser when the plurality of connection leads 3 are manufactured, the normal operation of the display panel 10 is not affected.

In some embodiments, an orthographic projection of the first light-blocking layer 21 on the first surface 1a of the substrate 1 is substantially overlapped with the first surface 1a of the substrate 1, and borders of the orthographic projection of the first light-blocking layer 21 on the first surface 1a of the substrate 1 are surrounded by borders of the first surface 1a of the substrate 1.

In some other embodiments, the first light-blocking layer 21 is only disposed between a region covered by the first portions 31 of the connection leads 3 and the substrate 1, and a border of the orthographic projection of the first light-blocking layer 21 on the first surface 1a of the substrate 1 is farther from the second portions 32 of the plurality of connection leads 3 than a corresponding border of the region covered by the first portions 31 of the connection leads 3.

In the manufacturing process of the display panel 10, the light-blocking layer 2 mainly functions to prevent photons of the laser from penetrating and reacting with the film layer structures on the front of the display panel 10 to generate heat when the plurality of connection leads 3 are manufactured by the laser etching process. Therefore, it is necessary to ensure the light-blocking layer 2 to be distributed at positions of laser etching. However, the manufacturing process of the display panel 10 further includes other laser processes.

For example, when the display panel 10 is manufactured, firstly, film layer structures required by the display panel are prepared on a whole initial substrate, and an initial light-blocking layer is formed on a surface of the initial substrate. The initial light-blocking layer is of, for example, an integral planar structure, and covers the entire surface of the initial substrate. Next, the entire initial substrate with the required film layer structures is cut, for example, by laser, so that the initial substrate is divided, along a cutting line, into a plurality of substrates on each of which the light-blocking layer is formed but the plurality of connection leads are not formed.

In this process, since the initial light-blocking layer covers the entire surface of the initial substrate, when the entire initial substrate with the required film layer structures is cut by the laser, the effect of the laser cutting is affected due to the presence of the light-blocking layer at the position of the cutting line, and defects such as edge chipping and burrs are further generated on an edge of a cut portion of the light-blocking layer along the cutting line, which results in poor adhesion of edge portions of the light-blocking layers on respective surfaces of the plurality of substrates obtained by cutting to the respective surfaces of the substrates.

Therefore, in some embodiments, in the manufacturing of the light-blocking layers, firstly, a plurality of light-blocking layers are manufactured on the entire initial substrate. The entire initial substrate may be divided into a plurality of substrate partitions. Each light-blocking layer is located in a substrate partition, and the light-blocking layer has a certain distance from a boundary region of the substrate partition. After the initial substrate is cut to obtain the plurality of substrates, the surface of the substrate is provided with the light-blocking layer, and the effect of the laser cutting is not affected by the light-blocking layer during cutting. The structure of the finally obtained display panel is as follows.

In some embodiments, as shown in FIGS. 9, 10, 13A, 13B and 14, borders of the light-blocking layer 2 (e.g., the first light-blocking layer(s) 21 and the second light-blocking layer 22 (s)) each have a certain distance from a corresponding side of the surface of the substrate 1. That is, the light-blocking layer 2 is not arranged next to sides of the surface of the substrate 1. By reserving the certain distance, on the basis that the light-blocking layer 2 functions to block the laser, an adhesion degree of the light-blocking layer 2 and the substrate 1 is able to be ensured, and other laser manufacturing processes in the manufacturing process of the display panel is able to be facilitated.

It will be understood that, due to scratching of other components of the display panel 10 and the edges of the light-blocking layer 2 in a manufacturing process of the other components of the display panel 10, the use of such design is able to effectively prevent a portion of the substrate 1 covered by the light-blocking layer 2 from being exposed caused by peeling of edges of the light-blocking layer 2 from the substrate 1, thereby avoiding a problem that the light-blocking layer 2 cannot achieve the desired light-blocking effect.

Next, the certain distance is reserved between the border of the light-blocking layer 2 and the corresponding side of the surface of the substrate 1. That is, the borders of the light-blocking layer 2 on the surface of the substrate 1 are surrounded by the borders of the surface of the substrate 1, and an area of the light-blocking layer 2 is less than an area of the surface of the substrate 1, so that a covering area of the light-blocking layer 2 on the substrate 1 and the adhesion degree of the light-blocking layer 2 and the substrate 1 are able to be ensured.

The surface of the substrate 1 refers to the first surface 1a and/or the second surface 1b of the substrate 1. In some examples, the light-blocking layer 2 includes only the first light-blocking layer(s) 21. Then, the distance between the border of the light-blocking layer 2 and the corresponding side of the surface of the substrate 1 refers to a distance between a border of the first light-blocking layer 21 and a corresponding side included in the first surface 1a of the substrate 1. In some other examples, the light-blocking layer 2 includes the second light-blocking layer(s) 22 in addition to the first light-blocking layer(s) 21. Then, the distance between the border of the light-blocking layer 2 and the corresponding side of the surface of the substrate 1 further refers to a distance between a border of the second light-blocking layer 22 and a corresponding side included in the second surface 1b of the substrate 1.

Next, the set distance between the border of the light-blocking layer 21 and the corresponding side of the first surface 1a and/or the second surface 1b of the substrate 1 may also be used as a laser clearance distance. As described above, the initial light-blocking layer as a whole layer is manufactured on the initial substrate, so that when the initial substrate is cut by the laser, the problem of poor adhesion between the edge portion of the light-blocking layer and the surface of the substrate occurs. Therefore, the initial light-blocking layer on the initial substrate is manufactured as a plurality of mutually independent patterns, and each of which is located in a region surrounded by cutting lines. When the initial substrate is cut, the cutting line is located between two adjacent light-blocking layers formed on the surface of the initial substrate. This effectively avoids the problem of poor adhesion between the edges of the light-blocking layer 2 and the substrate 1 in the manufacturing process of the display panel 10.

In some embodiments, cutting the entire initial substrate to obtain the plurality of substrates may be performed in other ways than the laser cutting, such as glass knife cutting or water jet cutting, which is not be affected by the initial light-blocking layer, so that there is no need to reserve a laser clearance distance. In this way, the initial light-blocking layer covers the entire surface of the initial substrate. In the obtained plurality of substrates, the light-blocking layer 2 is arranged next to the sides of the surface of the substrate 1, so that the distance between the border of the light-blocking layer and the corresponding side of the surface of the substrate may be zero. For example, a border of the first light-blocking layer 21 proximate to a selected side of the first surface coincides with the selected side.

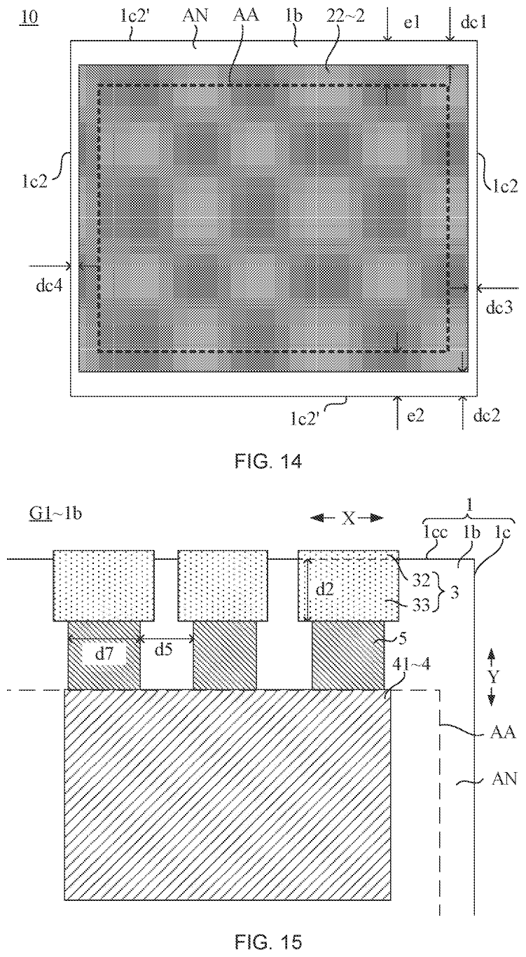

For example, a distance (e.g., d9 or d10 shown in FIG. 9, or dc1 or dc2 shown in FIG. 14) between a border, proximate to the selected side surface 1cc of the substrate 1, of the orthographic projection of the light-blocking layer 2 on the substrate 1 and a side, connected to the selected side surface 1cc of the substrate 1, in a plurality of sides included in the surface of the substrate 1 on which the light-blocking layer 2 is disposed is greater than or equal to zero, and is less than a distance (e.g., e1 or e2 shown in FIGS. 6, 8 and 14) between a border of the display region AA proximate to the selected side surface 1cc of the substrate 1 and the selected side surface 1cc of the substrate 1.

In some embodiments, as shown in FIGS. 9 and 10, the light-blocking layer 2 includes the first light-blocking layer(s) 21, and the surface of the substrate 1 on which the light-blocking layer 2 is disposed refers to the first surface 1a of the substrate 1. A distance (e.g., d9 or d10 shown in FIG. 9) between a border, proximate to the selected side surface 1cc of the substrate 1, of the orthographic projection of the first light-blocking layer 21 on the substrate 1 and a first selected side 1c1′ included in the first surface 1a of the substrate 1 is greater than or equal to zero, and is less than the distance (e.g., e1 or e2 shown in FIG. 14) between the border of the display region AA proximate to the selected side surface 1cc of the substrate 1 and the selected side surface 1cc of the substrate 1. That is, the border, proximate to the selected side surface 1cc of the substrate 1, of the orthographic projection of the first light-blocking layer 21 on the substrate 1 coincides with or has a set distance from the first selected side 1c1′, and the set distance is less than the distance between the border of the display region AA proximate to the selected side surface 1cc of the substrate 1 and the selected side surface 1cc of the substrate 1.

In some embodiments, as shown in FIGS. 13A, 13B and 14, the light-blocking layer 2 further includes the second light-blocking layer(s) 22, and the surface of the substrate 1 on which the light-blocking layer 2 is disposed refers to the second surface 1b of the substrate 1. A distance (e.g., dc1 or dc2 shown in FIG. 14) between a border, proximate to the selected side surface 1cc of the substrate 1, of an orthographic projection of the second light-blocking layer 22 on the substrate 1 and a second selected side 1c2′ included in the second surface 1b of the substrate 1 is greater than or equal to zero, and is less than the distance (e.g., e1 or e2 shown in FIG. 14) between the border of the display region AA proximate to the selected side surface 1cc of the substrate 1 and the selected side surface 1cc of the substrate 1. That is, the border, proximate to the selected side surface 1cc of the substrate 1, of the orthographic projection of the second light-blocking layer 22 on the substrate 1 coincides with or has a set distance from the second selected side 1c2′, and the set distance is less than the distance between the border of the display region AA proximate to the selected side surface 1cc of the substrate 1 and the selected side surface 1cc of the substrate 1.

In some embodiments, as shown in FIGS. 4 to 8, the light-blocking layer 2 includes the first light-blocking layer(s) 21 located on the first surface 1a of the substrate 1.

As shown in FIGS. 9 and 10, the borders of the orthographic projection of the first light-blocking layer 21 on the first surface 1a of the substrate 1 are surrounded by the borders of the first surface 1a of the substrate 1; that is, an area of the first surface 1a of the substrate 1 is greater than an area of the orthographic projection of the first light-blocking layer 21 on the first surface 1a of the substrate 1; and/or as shown in FIG. 14, borders of the orthographic projection of the second light-blocking layer 22 on the second surface 1b of the substrate 1 are surrounded by borders of the second surface 1b of the substrate 1; that is, an area of the second surface 1b of the substrate 1 is greater than an area of the orthographic projection of the second light-blocking layer 22 on the second surface 1b of the substrate 1.

For example, as shown in FIGS. 6 and 7, the light-blocking layer 2 further includes the second light-blocking layer(s) 22 disposed on the second surface 1b of the substrate 1. The second surface 1b of the substrate 1 has the display region AA and the peripheral region(s) AN respectively located on at least one side of the display region AA. As shown in FIGS. 13A, 13B and 14, the orthographic projection of the second light-blocking layer 22 on the second surface 1b of the substrate 1 covers at least a portion, overlapped with the display region AA, of a region of the second surface 1b of the substrate 1 corresponding to the wiring region BB.

In some embodiments, as shown in FIG. 13A, the orthographic projection of the second light-blocking layer 22 on the second surface 1b of the substrate 1 is overlapped with or substantially overlapped with the portion, overlapped with the display region AA, of the region of the second surface 1b of the substrate 1 corresponding to the wiring region BB.

In some other embodiments, as shown in FIG. 13B, the orthographic projection of the second light-blocking layer 22 on the second surface 1b of the substrate 1 surrounds the portion, overlapped with the display region AA, of the region of the second surface 1b of the substrate 1 corresponding to the wiring region BB.

In yet other embodiments, as shown in FIG. 14, the orthographic projection of the second light-blocking layer 22 on the second surface 1b of the substrate 1 is completely overlapped with the display region AA; or the borders of the orthographic projection of the second light-blocking layer 22 on the second surface 1b of the substrate 1 are closer to respective sides of the second surface 1b of the substrate 1 than respective borders of the display region AA.

As shown in FIG. 14, the region of the second surface 1b of the substrate 1 corresponding to the wiring region BB refers to a region corresponding to an orthographic projection, on the second surface 1b of the substrate 1, of the wiring region BB of the first surface 1a of the substrate 1.

In this way, the second light-blocking layer 22 is able to cover at least a region of the display region AA that is overlapped with the region of the second surface 1b of the substrate 1 corresponding to the wiring region BB, and the second light-blocking layer 22 is located between an entirety of the driving circuit layer 6 and the light-emitting device layer 4 and the substrate 1. Therefore, in the manufacturing process of the display panel 10, for example, the problem of the damage to the front film layers, due to the fact that the laser emitted from the back or side of the display panel 10 is irradiated into the front display region AA, is able to be effectively avoided.

For example, the light-blocking layer 2 may cover the entire surface of the substrate 1, or only a region between the plurality of connection leads 3 and the substrate 1. There are following cases.

In some embodiments, as shown in FIGS. 9 and 10, the light-blocking layer 2 includes the first light-blocking layer 21 disposed on the first surface 1a of the substrate 1, and the first surface 1a of the substrate 1 has the wiring region(s) BB and a non-wiring region BN. The wiring region(s) BB are closer to respective selected side surface(s) 1cc of the substrate 1 than the non-wiring region BN, and the first portions 31 of the plurality of connection leads 3 are located in the wiring region(s) BB. Two wiring regions BB shown in FIGS. 9 and 10 correspond to a case that the substrate 1 shown in FIG. 2A has two selected side surfaces 1cc opposite to each other. For a case that the substrate 1 has a single selected side surface 1cc, the first surface 1a of the substrate 1 has a single wiring region BB, which is also applicable to in these embodiments.

The first surface 1a of the substrate 1 includes the plurality of sides 1c1. The first light-blocking layer 21 is located in the wiring region(s) BB and the non-wiring region BN of the first surface 1a of the substrate 1, and there is a set distance between a border of the orthographic projection of the first light-blocking layer 21 on the first surface 1a of the substrate 1 and a corresponding side 1c1 of the first surface 1a of the substrate 1 the sides 1c1 of a surface 1a. The set distances are, for example, d9 to d12 in FIG. 9.

In the above embodiments, the border of the orthographic projection of the first light-blocking layer 21 and the corresponding side 1c1 of the first surface 1a has the set distance therebetween. By reserving a certain distance, under the basis of ensuring that the light-blocking layer 2 functions to block the laser, the adhesion degree of the light-blocking layer 2 and the substrate 1 is able to be ensured, and other laser processes are able to be facilitated in the manufacturing process of the display panel 10.

Furthermore, as shown in FIGS. 3A and 3B, the wiring region BB of the first surface 1a of the substrate 1 includes a bonding region BA, and the first portions 31 of the plurality of connection leads 3 located on the first surface 1a of the substrate 1 are bonded to the flexible printed circuit 7 in the bonding region BA.

In some other embodiments, as shown in FIG. 10, the light-blocking layer 2 includes the first light-blocking layer(s) 21 disposed on the first surface 1a of the substrate 1, and the first surface 1a of the substrate 1 has the wiring region(s) BB and the non-wiring region BN. The wiring region(s) BB are closer to the respective selected side surface(s) 1cc of the substrate 1 than the non-wiring region BN, and the first portions 31 of the plurality of connection leads 3 are located in the wiring region(s) BB.

The first surface 1a of the substrate 1 includes the plurality of sides 1c1. The first light-blocking layer(s) 21 are respectively located in the wiring region(s) BB of the first surface 1a of the substrate 1, and the border of the orthographic projection of the first light-blocking layer 21 on the first surface 1a of the substrate 1 and the corresponding side 1c1 of the first surface 1a of the substrate 1 have the set distance therebetween. The set distances are, for example, d10 to d12 in FIG. 10.

In the above embodiments, the border of the orthographic projection of the first light-blocking layer 21 and the corresponding side 1c1 of the first surface 1a has the set distance therebetween. By reserving a certain distance, under the basis of ensuring that the light-blocking layer 2 functions to block the laser, the adhesion degree of the light-blocking layer 2 and the substrate 1 is able to be ensured, and other laser processes are able to be facilitated in the manufacturing process of the display panel 10.

In some examples, as shown in FIG. 14, the second light-blocking layer 22 is disposed on the second surface 1b of the substrate 1, and the second light-blocking layer 22 is a whole film layer covering the display region AA. In this case, each display panel 10 includes a single second light-blocking layer 22.

In some other examples, as shown in FIGS. 13A and 13B, the second light-blocking layer(s) 22 are disposed on the second surface 1b of the substrate 1, and there is a set distance between a border of the orthographic projection of the second light-blocking layer 22 on the second surface 1b of the substrate 1 and a corresponding side of the second surface 1b of the substrate 1. In this case, as shown in FIG. 13A, the second light-blocking layer 22 does not cover the entire region of the display region AA, but is located at least in a region corresponding to the portion, overlapped with the display region AA, of the region of the second surface 1b of the substrate 1 corresponding to the wiring region BB. Moreover, in this case, the number of the second light-blocking layer(s) 22 is the same as the number of the wiring region(s) BB. That is, in a case where the display panel 10 includes a single wiring region BB, the display panel 10 includes a single second light-blocking layer 22. In a case where the display panel 10 includes two wiring regions BB opposite to each other, the display panel 10 includes two second light-blocking layers 22 opposite to each other.

Furthermore, as shown in FIG. 13B, a border, away from the selected side surface 1cc of the substrate 1, of the orthographic projection of the second light-blocking layer 22 on the substrate 1 is farther from the selected side surface 1cc of the substrate 1 than a border of the wiring region BB away from the selected side surface 1cc of the substrate 1. The first portions 31 of the plurality of connection leads 3 are located in the wiring region(s) BB. It will be understood that the border, away from the selected side surface 1cc of the substrate 1, of the orthographic projection of the second light-blocking layer 22 on the substrate 1 is farther from the selected side surface 1cc of the substrate 1 than a border, away from the selected side surface 1cc of the substrate 1, of an orthographic projection, on the substrate 1, of first portions 31 of connection leads 3 in the wiring region BB corresponding to the second light-blocking layer 22.

Moreover, in a case where the first light-blocking layer 21 is located in the wiring region BB, and the second light-blocking layer 22 is disposed in the region corresponding to the wiring region BB on the second surface 1b of the substrate 1, the orthographic projections of the first light-blocking layer 21 and the second light-blocking layer 22 on the same surface (i.e., the first surface 1a or the second surface 1b) of the substrate 1 are overlapped or substantially overlapped.

In order to clearly describe the first light-blocking layer 21 located in the wiring region BB, structures of the first portions 31 of the connection leads 3 distributed in the wiring region BB will be described below.

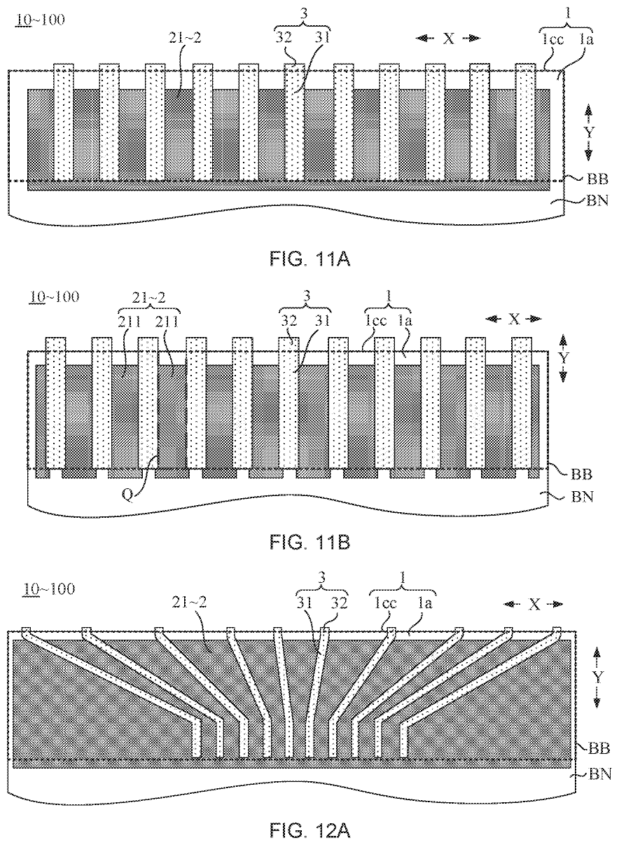

In some embodiments, as shown in FIGS. 3A, 11A and 11B, the first portions 31 of the connection leads 3 located on the first surface 1a of the substrate 1 are linear. The wiring region BB includes the bonding region BA, and a portion of each of the first portions 31 of the connection leads 3 located in the bonding region BA is configured to be bonded to the flexible printed circuit 7.

As shown in FIGS. 3A and 3B, a dimension k1 of the selected side surface 1cc of the substrate 1 in a first direction X is greater than a dimension k2 of a region covered by the connection leads 3 in the first direction X.

Furthermore, a plurality of first portions 31 are arranged side by side, and extend in a direction perpendicular to the selected side surface 1cc. Furthermore, the plurality of first portions 31 are equally spaced.

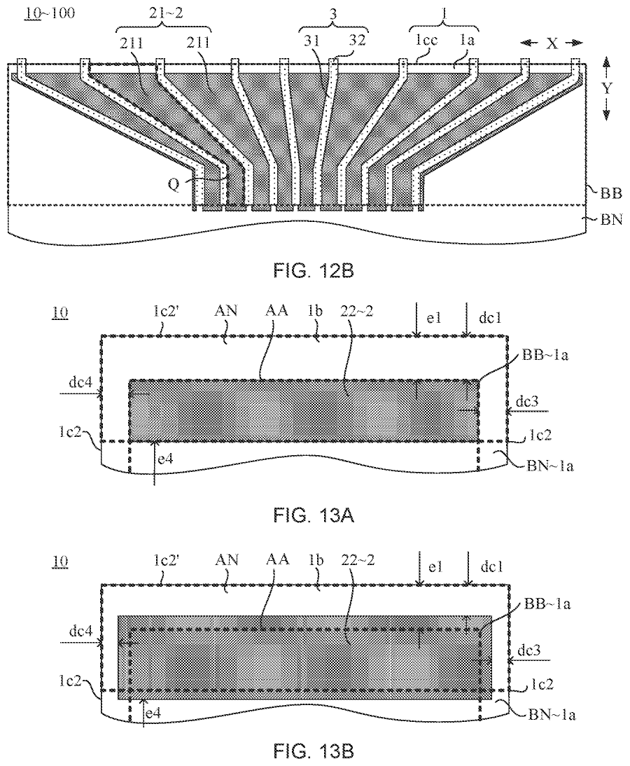

In some other embodiments, as shown in FIGS. 3B, 12A and 12B, the first portions 31 of the connection leads 3 located on the first surface 1a of the substrate 1 are curved and bent. The wiring region BB includes the bonding region BA, and the bonding region BA is located on a side of the wiring region BB away from the selected side surface 1cc of the substrate 1.

Furthermore, as shown in FIG. 3B, the first portions 31 of the connection leads 3 each include the first sub-line 31a, the second sub-line 31b and the third sub-line 31c. A portion, connected to the second portion 32, of the first portion 31 of each of the connection leads 3 is the first sub-line 31a. A portion, farthest from the substrate 1, of the first portion 31 of each of the connection leads 3 is the third sub-line 31c. A middle portion of the first portion 31 of each of the connection leads 3 is the second sub-line 31b. A plurality of third sub-lines 31c are located in the bonding region BA, and are configured to be bonded to the flexible printed circuit 7.

Furthermore, as shown in FIG. 3B, the connection leads 3 are arranged side by side in the first direction X. The dimension k1 of the selected side surface 1cc of the substrate 1 in the first direction X is greater than a dimension k2 of a region covered by a plurality of first sub-lines 31a in the first direction X. The dimension k2 of the region covered by the plurality of first sub-lines 31a in the first direction X is greater than a dimension k3 of the bonding region BA in the first direction X. Moreover, the dimension k3 of the bonding region BA in the first direction X is greater than a dimension k4 of a region covered by a plurality of third sub-lines 31c in the first direction X. The plurality of third sub-lines 31c are inwardly gathered relative to the plurality of first sub-lines 31a, which is suitable for the flexible printed circuit 7 with a small size.

An end of the first portion 31 of each of the plurality of connection leads 3 away from the selected side surface 1cc is referred to as a first end of the first portion 31. Accordingly, a portion of the first light-blocking layer 21 away from the selected side surface is referred to as a first end of the first light-blocking layer 21. The first light-blocking layer 21 is located in the wiring region BB, and covers all of portions of the first portions 31 of the connection leads 3 in a region corresponding to the display region AA. That is, when the first portions 31 of the plurality of connection leads 3 are formed by the laser etching, the laser does not pass through the first light-blocking layer 21, and does not travel to the film layer structures in the display region AA.

Furthermore, as shown in FIG. 10, the light-blocking layer 2 includes the first light-blocking layer 21(s) disposed on the first surface 1a of the substrate 1, and the first light-blocking layer 21 is located in the wiring region BB of the first surface 1a of the substrate 1. A border, away from the selected side surface 1cc of the substrate 1, of the orthographic projection of the first light-blocking layer 21 on the first surface 1a of the substrate 1 is farther from the substrate 1 than borders of the connection leads 3 away from the selected side surface 1cc of the substrate 1.

The border of the first light-blocking layer 21 away from the selected side surface 1cc of the substrate 1 is farther from the selected side surface 1cc of the substrate 1 than the borders of the connection leads 3 away from the selected side surface 1cc of the substrate 1. It will be understood that a distance between the border of the first light-blocking layer 21 away from the selected side surface 1cc and the selected side surface 1cc is greater than a distance between a border, away from the selected side surface 1cc, of a region covered by the first portions 31 of the connection leads 3 and the selected side surface 1cc.

This is able to better protect the front film layer structures, compared with a design in which the border of the first light-blocking layer 21 away from the selected side surface 1cc is flush with the border, away from the selected side surface 1cc, of the region covered by the first portions 31 of the connection leads 3, i.e., the distance between the border of the first light-blocking layer 21 away from the selected side surface 1cc and the selected side surface 1cc is equal to the distance between the border, away from the selected side surface 1cc, of the region covered by the first portions 31 of the connection leads 3 and the selected side surface 1cc. It will be understood that when the plurality of connection leads 3 are formed by the laser etching, a path of the laser is dynamic. When the first end of the first portion 31 of the connection lead 3 is formed by the laser etching, in order to completely separate the first portions 31 of the connection leads 3 to avoid a short circuit between the connection leads 3 caused by a residual connection between the first ends of the first portions 31, a problem that a region irradiated by the laser exceeds the region covered by the first portions 31 of the connection leads 3 may exist. Since the border of the first light-blocking layer 21 is farther from the selected side surface 1cc, when the laser is irradiated onto the first light-blocking layer 21, the laser is able to be effectively blocked by the first light-blocking layer 21, and is not irradiated to the front of the display panel 10 to avoid the damage to the front film layers.

As shown in FIGS. 11A and 12A, in a case where the first light-blocking layer 21 is located in the wiring region BB, for the case that the first portion 31 of the connection lead is linear and/or the case that the first portion 31 of the connection lead is curved and bent, in some embodiments, the first light-blocking layer 21 may be an integral pattern located in the wiring region BB, and the orthographic projection of the first light-blocking layer 21 on the substrate 1 is overlapped with orthographic projections of the first portions 31 of all of the connection leads on the substrate 1.

In some other embodiments, as shown in FIGS. 11B and 12B, in the case where the first light-blocking layer 21 is located in the wiring region BB, the first light-blocking layer 21 includes a plurality of first light-blocking patterns 211. In the first portions 31 of the connection leads 3, a portion, located in the wiring region BB, of a region between first portions 31 of every two adjacent connection leads 3 is a gap region Q. The first light-blocking layer 21 includes the plurality of first light-blocking patterns 211. An orthographic projection of each of the plurality of first light-blocking patterns 211 on the first surface 1a of the substrate 1 covers at least a portion of an orthographic projection of the gap region Q on the first surface 1a of the substrate 1 that is overlapped with an orthographic projection of the light-emitting device layer 4 on the first surface 1a of the substrate 1.

In some embodiments, there is a certain interval between two adjacent first light-blocking patterns 211. A dimension d3 of each first light-blocking pattern 211 in the direction perpendicular to the substrate 1 is greater than or equal to 0.03 μm. The dimension d3 of the first light-blocking pattern 211 in the direction perpendicular to the substrate 1 is, for example, 0.03 μm, 0.04 μm or 0.05 μm.

The first light-blocking layer 21 includes the plurality of first light-blocking patterns 211, and the plurality of first light-blocking patterns 211 are spaced apart from each other. In this way, compared with the case that the first light-blocking layer 21 is the integral pattern, the first light-blocking pattern 211 has a smaller thickness. Moreover, in a direction perpendicular to the extending direction of the first portion 31 of the connection lead 3, portions of the first portion 31 of the connection lead 3 respectively located on two sides thereof are respectively disposed on the first light-blocking patterns 211, and a portion of the first portion 31 of the connection lead 3 located at a middle thereof is directly disposed on the substrate 1. Thus, the adhesion between the first portion 31 of the connection lead 3 and the first surface 1a of the substrate 1 is able to be improved.

Moreover, when the light-blocking layer 2 is damaged, e.g., is mechanically damaged caused by bumping, or when the plurality of connection leads 3 are formed by the laser etching, the laser is irradiated onto the light-blocking layer 2 to cause damage to the light-blocking layer 2. A thickness of a damaged portion of the light-blocking layer 2 is reduced compared with a thickness at another position, so that when the reliability test is performed in the subsequent manufacturing process of the display panel 10, water vapor enters the damaged portion of the light-blocking layer 2. Furthermore, the water vapor entering the damaged portion of the light-blocking layer 2 may spread to the first portion 31 of the connection lead 3. When the first portion 31 is in contact with the water vapor, on one hand, the first portion 31 is corroded by water and oxygen, and on another hand, a risk of peeling of the first portion 31 is generated.

By arranging the plurality of first light-blocking patterns 211 spaced apart from each other, even if one or more light-blocking patterns 211 are damaged during the laser etching process, only first portion(s) 31 of connection lead(s) 3 adjacent to the damaged light-blocking patterns 211 may be affected, and the rest is not be affected, so that when the problem of water and oxygen corrosion due to the fact that the first portion(s) 31 of one or more of the connection leads 3 are affected by water vapor in the subsequent reliability test occurs, a problem of series corrosion due to spreading of water vapor to positions of first portions 31 of other connection leads 3 is avoided.

In some embodiments, a border, proximate to the selected side surface 1cc, of an orthographic projection of the first light-blocking pattern 211 on the first surface 1a of the substrate 1 is located within the orthographic projection of the gap region Q on the first surface 1a of the substrate 1. A border, away from the selected side surface 1cc, of the orthographic projection of the first light-blocking pattern 211 on the first surface 1a of the substrate 1 is flush with or substantially flush with a border, away from the selected side surface 1cc, of the orthographic projection of the gap region Q on the first surface 1a of the substrate 1.

In some other embodiments, as shown in FIGS. 11A, 12A and 17, a distance d16 between a border, away from the selected side surface 1cc, of an orthographic projection of each first light-blocking pattern 211 on the first surface 1a of the substrate 1 and the selected side surface 1cc, is greater than a distance d15 between a border, away from the selected side surface 1cc, of an orthographic projection of a gap region Q corresponding to this first light-blocking pattern 211 on the first surface 1a of the substrate 1 and the selected side surface 1cc. Moreover, the distance d16 between the border, away from the selected side surface 1cc, of the orthographic projection of each first light-blocking pattern 211 on the first surface 1a of the substrate 1 and the selected side surface 1cc, is greater than a distance d1 between the border of the wiring region BB away from the selected side surface 1cc and the selected side surface 1cc. The distance d15 between the border, away from the selected side surface 1cc, of the orthographic projection of the gap region Q corresponding to the first light-blocking pattern 211 on the first surface 1a of the substrate 1 and the selected side surface 1cc, is less than or equal to the distance d1 between the border of the wiring region BB away from the selected side surface 1cc and the selected side surface 1cc.

By lengthening the dimension of the first light-blocking pattern 211 in a length direction (i.e., direction perpendicular to the selected side surface 1cc) of the first portion 31 of the connection lead 3, the first light-blocking pattern 211 is able to better cover the gap region Q (i.e., a region to be cut by the laser) between first portions 31 of two adjacent connection leads 3. Furthermore, the laser is prevented from passing through the gap region Q between the first portions 31 of the two connection leads 3, so as to be prevented from being irradiated onto the film layers on the front of the display panel 10.

In some embodiments, the second light-blocking layer 22 includes a plurality of second light-blocking patterns. The plurality of second light-blocking patterns are located in the region of the second surface 1b of the substrate 1 corresponding to the wiring region BB. In the first portions 31 of the plurality of connection leads 3, the region between the first portions 31 of every two adjacent connection leads 3 is a gap region, and an orthographic projection of each of the plurality of second light-blocking patterns on the second surface 1b of the substrate 1 covers at least a region of the second surface 1b of the substrate 1 corresponding to a portion of an orthographic projection of a gap region on the first surface 1a of the substrate 1 that is overlapped with the orthographic projection of the light-emitting device layer 4 on the first surface 1a of the substrate 1.

For example, the light-blocking layer 2 includes the first light-blocking layer(s) 21 and the second light-blocking layer(s) 22. The first light-blocking layer 21 includes the plurality of first light-blocking patterns 211 as described above, and the second light-blocking layer 22 includes the plurality of second light-blocking patterns. The orthographic projection of each second light-blocking pattern on the second surface 1b of the substrate 1 covers at least a region of the second surface 1b of the substrate 1 corresponding to a first light-blocking pattern 211.

The shapes and thicknesses of the plurality of second light-blocking patterns are respectively the same as those of the plurality of first light-blocking patterns 211 included in the first light-blocking layer 21, and will not be repeated here.

It will be noted that this is only described as an example. In a case where the first light-blocking layer 21 is the integral film layer as shown in FIG. 9 or 10, the design in which the second light-blocking layer 22 includes the plurality of second light-blocking patterns may still be used.

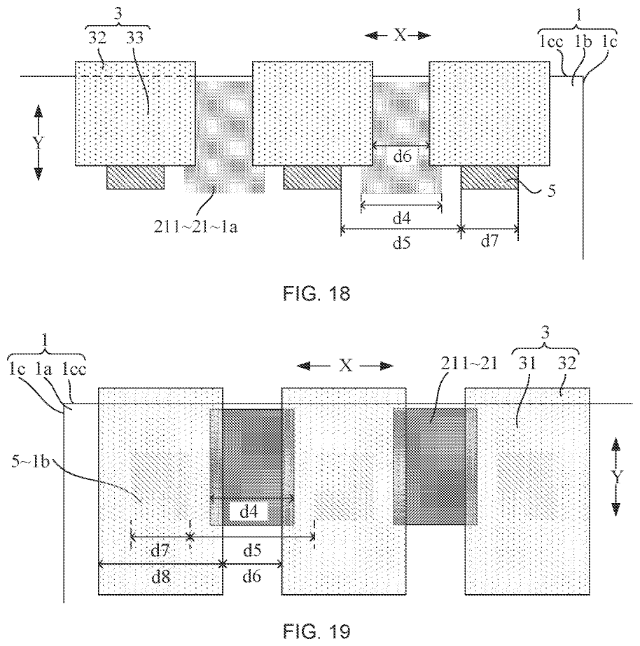

In some embodiments, as shown in FIGS. 15 and 16, the display panel 10 further includes a plurality of electrodes 5 disposed on the second surface 1b of the substrate 1. Each of the plurality of electrodes 5 is connected to a third portion 33 of a connection lead 3. The light-blocking layer 2 includes the first light-blocking layer(s) 21 disposed on the side of the substrate 1 where first surface 1a is located, and the first light-blocking layer 21 includes the plurality of first light-blocking patterns 211. As shown in FIG. 18, a dimension d4 of the first light-blocking pattern 211 in the first direction X perpendicular to the extending direction Y thereof is less than a distance d5 between two electrodes 5 to which two connection leads 3 corresponding to the first light-blocking pattern 211 are respectively electrically connected.

In some embodiments, as shown in FIGS. 15 and 16, electrodes 5 are arranged side by side, and an end of each of the electrodes 5 facing the selected side surface 1cc of the substrate 1 is on a straight line. That is, the end of each of the electrodes 5 facing the selected side surface 1cc of the substrate 1 is flush.

In some examples, as shown in FIGS. 18 and 19, the dimension d4 of the first light-blocking pattern 211 in the first direction X perpendicular to the extending direction Y thereof is greater than or equal to a distance d6 between first portions 31 of two connection leads 3 corresponding to the first light-blocking pattern 211. The distance d6 between the first portions 31 of two connection leads 3 corresponding to the first light-blocking pattern 211 is a dimension of the gap region Q corresponding to the first light-blocking pattern 211 in a direction (i.e., first direction X) perpendicular to an extending direction Y of the gap region.

It will be understood that, as a portion of the light-blocking layer 2, the first light-blocking pattern 211 has the same function as the light-blocking layer 2. Therefore, the first light-blocking pattern 211 fills at least a portion between the first portions 31 of two adjacent connection leads 3 adjacent thereto. That is, the dimension d4 of the first light-blocking pattern 211 in the first direction X perpendicular to the extending direction Y thereof is at least equal to the distance d6 between the first portions 31 of the two connection leads 3 corresponding to the first light-blocking pattern 211.

Furthermore, as shown in FIGS. 18 and 19, the dimension d4 of the first light-blocking pattern 211 in the first direction X perpendicular to the extending direction Y thereof is greater than the distance d6 between the first portions 31 of the two connection leads 3 corresponding to the first light-blocking pattern 211. Since in the first direction X perpendicular to the extending direction of the first portion 31 of the connection lead 3, the first light-blocking pattern 211 not only fills the gap between the first portions 31 of two adjacent connection leads 3 corresponding thereto, but also is partially overlapped with the first portions 31 of the two adjacent connection leads 3. In this way, the first light-blocking pattern 211 is able to be better ensured to block the laser, so that the laser is not irradiated into the display region AA by passing through the gap between the first portions 31 of the two connection leads 3.

For example, as shown in FIGS. 4 to 8, the electrodes 5 are closer to the selected side surface 1cc of the substrate 1 than the light-emitting device layer 4. The plurality of electrodes 5 are configured to be electrically connected to the driving circuit layer 6. The driving circuit layer 6 is coupled to the light-emitting device layer 4, and is configured to drive the light-emitting device layer 4 to emit light. The plurality of electrodes 5 receive respective driving signals transmitted from the plurality of connection leads 3, and transmit the respective driving signals to the driving circuit layer 6, so as to control the light-emitting device layer 4 to emit light.

For example, as shown in FIGS. 4 to 8, the electrodes 5 are disposed at a position of the second surface 1b close to the selected side surface 1cc. That is, the electrodes 5 are closer to a side in the sides of the second surface 1b connected to the selected side surface 1cc.

As shown in FIGS. 4 to 8, each of the plurality of connection leads 3 includes the first portion 31 located on the first surface 1a, the second portion 32 located on the selected side surface 1cc and the third portion 33 located on the second surface 1b of the substrate 1. Each connection lead 3 is electrically connected to one of the plurality of electrodes 5 located on the second surface 1b via the selected side face 1cc from the first surface 1a.

In some embodiments, as shown in FIGS. 18 and 19, the electrodes 5 are arranged side by side in the first direction X. A sum of the distance d6 between the first portions 31 of the two adjacent connection leads 3 and a dimension d8 of a first portion 31 of a connection lead 3 in the two adjacent connection leads 3 in the first direction X, is equal to a sum of the distance d5 between the two electrodes 5 to which the two adjacent connection leads 3 are respectively electrically connected and a dimension d7 of an electrode 5 in the two electrodes 5 in the first direction X, i.e., d6+d8=d5+d7.

As shown in FIGS. 18 and 19, for the dimension d8 of the first portion 31 of the connection lead 3 in the two adjacent connection leads 3 in the first direction X and the dimension d7 of the electrode 5 in the two electrodes 5 in the first direction X, the connection lead 3 and the electrode 5 are electrically connected to each other.

In some examples, in the plurality of connection leads 3, dimensions of first portions 31 of any two adjacent connection leads 3 in the first direction X are equal.

In some other examples, in the plurality of connection leads 3, the dimensions of the first portions 31 of any two adjacent connection leads 3 in the first direction X are different. The dimension of the first portion 31 of the connection lead 3 in the first direction X is positively correlated with the dimension d7 of the electrode 5 electrically connected to this connection lead 3 in the first direction X.

In some embodiments, as shown in FIGS. 15 and 16, the display panel 10 further includes the plurality of electrodes 5 disposed on the second surface 1b of the substrate 1. Each of the plurality of electrodes 5 is connected to a third portion 33 of a connection lead 3, and the electrodes 5 are arranged side by side in the first direction X. As shown in FIGS. 18 and 19, two adjacent electrodes 5 are respectively electrically connected to two adjacent connection leads 3. A difference between the distance d5 between the two adjacent electrodes 5 and the distance d6 between the first portions 31 of the two adjacent connection leads 3 is greater than a difference between the dimension d8 of the first portion 31 of the connection lead 3 in the two adjacent connection leads 3 in the first direction X and the dimension d7 of the electrode 5 electrically connected to this connection lead 3 in the first direction X, i.e., d5−d6=d8−d7.

In order to clearly describe the specific location of the light-blocking layer 2, as shown in FIG. 2A, a description will be made below in an example where the display panel 10 includes two opposite selected side surfaces 1cc.

For example, as shown in FIGS. 9 and 10, the first surface 1a of the substrate 1 includes the plurality of sides 1c1. In the plurality of sides 1c1 included in the first surface 1a of the substrate 1, sides proximate to respective selected side surface 1cc of the substrate 1 are first selected sides 1c1′. In the plurality of sides 1c1 included in the first surface 1a of the substrate 1, a distance between a border, proximate to a side 1c1 except the first selected sides 1c1′, of the orthographic projection of the first light-blocking layer 21 on the first surface 1a and the side 1c1 except the first selected sides 1c1′ is less than a distance between a border, proximate to the first selected side 1c1′, of the orthographic projection of the first light-blocking layer 21 on the first surface 1a and the first selected side 1c1′.

As shown in FIGS. 9 and 10, the distance between the border, proximate to the first selected side 1c1′, of the orthographic projection of the first light-blocking layer 21 on the first surface 1a and the first selected side 1c1′ in the plurality of sides 1c1 included in the first surface 1a of the substrate 1 is d9 or d10; the distance between the border, proximate to the side 1c1 except the first selected sides 1c1′, of the orthographic projection of the first light-blocking layer 21 on the first surface 1a and the side 1c1 except the first selected sides 1c1′ in the plurality of sides 1c1 included in the first surface 1a of the substrate 1 is d11 or d12; d9 is greater than d11, and d9 is greater than d12; d10 is greater than d11, and d10 is greater than d12.

In some embodiments, d9 is equal to d10.

In some other embodiments, d9 is not equal to d10.

In some embodiments, d11 is equal to d12.

In some other embodiments, d11 is not equal to d12.

For example, the distance between the border, proximate to the side 1c1 except the first selected sides 1c1′, of the orthographic projection of the first light-blocking layer 21 on the first surface 1a of the substrate 1 and the side 1c1 except the first selected sides 1c1′ in the plurality of sides 1c1 included in the first surface 1a of the substrate 1 is greater than or equal to 30 μm.

As shown in FIGS. 9 and 10, the distance between the border, proximate to the first selected side 1c1′, of the orthographic projection of the first light-blocking layer 21 on the first surface 1a and the first selected side 1c1′ included in the first surface 1a of the substrate 1 is d9 or d10; the distance between the border, proximate to the side 1c1 except the first selected sides 1c1′, of the orthographic projection of the first light-blocking layer 21 on the first surface 1a and the side 1c1 except the first selected sides 1c1′ in the plurality of sides 1c1 included in the first surface 1a of the substrate 1 is d11 or d12; d11 is greater than or equal to 30 μm, and d12 is greater than or equal to 30 μm.

d11 is, for example, 30 μm, 35 μm, or 40 μm.

d12 is, for example, 30 μm, 35 μm, or 40 μm.

It will be understood that in a case where one, two or more first light-blocking layers 21 are disposed on the substrate 1, distance relationships between borders of an orthographic projection of each first light-blocking layer 21 on the first surface 1a of the substrate 1 and the plurality of sides 1c1 included in the first surface 1a of the substrate 1 satisfy the above description.

It will be noted that in a case where each substrate 1 includes a single selected side surface 1cc and a single first light-blocking layer 21, and the first light-blocking layer 21 does not integrally cover the first surface 1a of the substrate 1, as shown in FIGS. 8 and 10, a distance e3 between a border, away from the first selected side 1c1′, of the orthographic projection of the first light-blocking layer 21 on the first surface 1a of the substrate 1 and a side 1c1 that this border faces is not subject to the above limitations.

For example, as shown in FIGS. 13A, 13B and 14, the light-blocking layer 2 further includes the second light-blocking layer(s) 22 disposed on the second surface 1b of the substrate 1. The second surface 1b of the substrate 1 includes a plurality of sides 1c2. In the plurality of sides 1c2 included in the second surface 1b of the substrate 1, sides proximate to respective selected side surfaces 1cc of the substrate 1 are second selected sides 1c2′. In the plurality of sides 1c2 included in the second surface 1b of the substrate 1, a distance between a border, proximate to the side 1c2 except the second selected sides 1c2′, of the orthographic projection of the second light-blocking layer 22 on the second surface 1b and the side 1c2 except the second selected sides 1c2′ is less than a distance between a border, proximate to the second selected side 1c2′, of the orthographic projection of the second light-blocking layer 22 on the second surface 1b and the second selected side 1c2′.

As shown in FIGS. 13A, 13B and 14, the distance between the border, proximate to the second selected side 1c2′, of the orthographic projection of the second light-blocking layer 22 on the second surface 1b and the second selected side 1c2′ in the plurality of sides 1c2 included in the second surface 1b of the substrate 1 is dc1 or dc2; the distance between the border, proximate to the side 1c2 except the second selected sides 1c2′, of the orthographic projection of the second light-blocking layer 22 on the second surface 1b and the side 1c2 except the second selected sides 1c2′ in the plurality of sides 1c2 included in the second surface 1b of the substrate 1 is dc3 or dc4; dc1 is greater than dc3, and dc1 is greater than dc4; dc2 is greater than dc3, and dc2 is greater than dc4.

In some embodiments, dc1 is equal to dc2.

In some other embodiments, dc1 is not equal to dc2.

In some embodiments, dc3 is equal to dc4.

In some other embodiments, dc3 is not equal to dc4.

It will be understood that in a case where the substrate 1 includes one, two or more second light-blocking layers 22, distance relationships between borders of an orthographic projection of each second light-blocking layer 22 on the second surface 1b of the substrate 1 and the plurality of sides 1c2 included in the second surface 1b of the substrate 1 satisfy the above description.

It will be noted that in a case where each substrate 1 includes a single selected side surface 1cc and a single second light-blocking layer 22, and the second light-blocking layer 22 does not integrally cover the second surface 1b of the substrate 1, as shown in FIGS. 8, 13A and 13B, a distance e4 between a border, away from the second selected side 1c2′, of the orthographic projection of the second light-blocking layer 22 on the second surface 1b of the substrate 1 and a side 1c2 that this border faces is not subject to the above limitations.

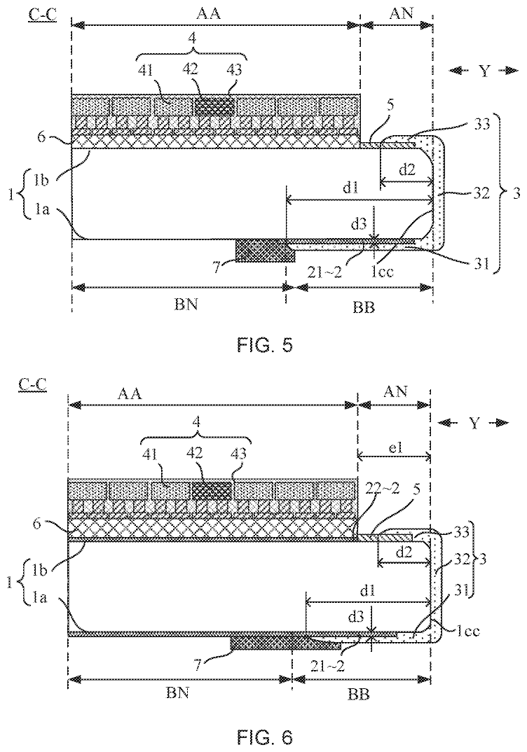

For example, the third portion 33 of each connection lead 3 on the second surface 1b is connected to an electrode 5. In some examples, as shown in FIGS. 5 to 8 and FIG. 18, the third portion 33 of each connection lead 3 on the second surface 1b and the electrode 5 are overlapped at a connection position. An end of the third portion 33 of the connected connection lead 3 away from the selected side surface 1cc of the substrate 1 is directly in contact with or electrically connected to an end of the electrode 5 proximate to the selected side surface 1cc of the substrate 1. In some other examples, the third portion 33 of each connection lead 3 on the second surface 1b is non-overlapped with the electrode 5 at the connection position. The end of the third portion 33 of the connected connection lead 3 away from the selected side surface 1cc of substrate 1 is directly in contact with or electrically connected to the end of the electrode 5 proximate to the selected side surface 1cc of the substrate 1.

Furthermore, as shown in FIGS. 4 to 8, the light-emitting device layer 4 includes the plurality of light-emitting devices 41, a plurality of pixel driving chips 42 and a protective film 43.

For example, as shown in FIGS. 2A and 2B, the display panel 10 includes sub-pixels P of at least three colors. The sub-pixels P of a plurality of colors include at least sub-pixels of a first color, sub-pixels of a second color and sub-pixels of a third color. The first color, the second color and the third color are three primary colors (e.g., red, green and blue, respectively).

For example, each sub-pixel P includes at least one light-emitting device 41.

In some examples, as shown in FIGS. 4 to 8, the protective film 43 includes a portion covering the plurality of light-emitting devices 41 and a portion filling gap regions between the plurality of light-emitting devices 41. For example, the protective film 43 may be made of black silicone or black resin. The protective film 43 is capable of protecting the plurality of light-emitting devices 41, so as to prevent the plurality of light-emitting devices 41 from being damaged in a process after the light-emitting devices 41 are formed.

For example, the light-emitting device 41 is, but is not limited to, an organic light-emitting diode (OLED), a mini light-emitting diode (Mini LED), or a micro light-emitting diode (Micro LED).

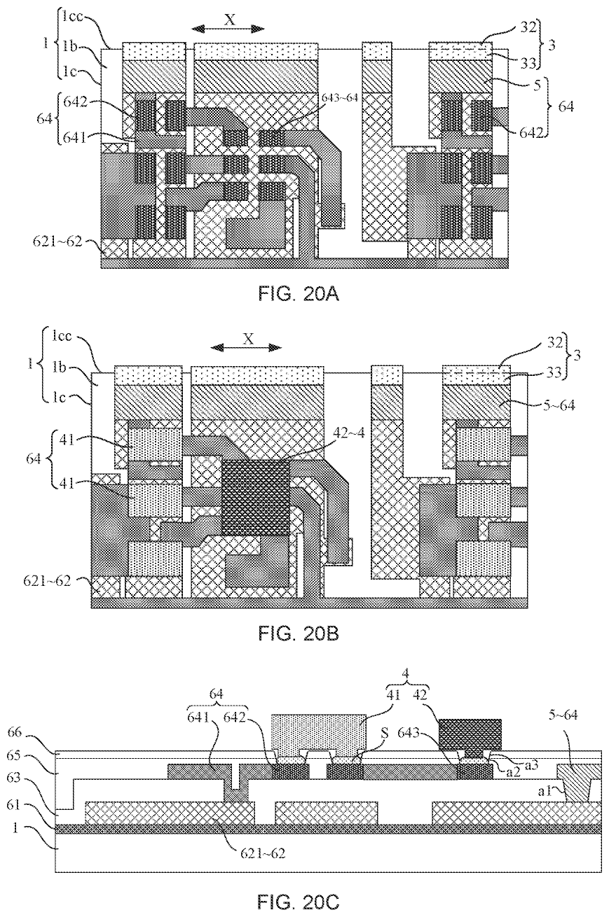

As shown in FIG. 20C, the driving circuit layer 6 includes a buffer layer 61, a first metal layer 62, an insulating layer 63, a second metal layer 64, a planarization layer 65 and a passivation layer 66 arranged in sequence from the substrate 1.

The buffer layer 61 is disposed on the first surface 1a of the substrate 1. The first metal layer 62 is disposed on a side of the buffer layer 61 away from the substrate 1, and includes a plurality of first signal lines 621. The insulating layer 63 is disposed on a side of the first metal layer 62 away from the substrate 1. The second metal layer 64 is disposed on a side of the insulating layer 63 away from the substrate 1, and includes the plurality of electrodes 5 and a plurality of second signal lines 641. The planarization layer 65 is disposed on a side of the second metal layer 64 away from the substrate 1. The passivation layer 66 is disposed on a side of the planarization layer 65 away from the substrate 1.

In some embodiments, as shown in FIGS. 20A and 20C, the second metal layer 64 further includes a plurality of connection pads. The plurality of connection pads include a plurality of first pads 642 connected to the light-emitting devices 41 and a plurality of second pads 643 connected to the pixel driving chips 42.

As shown in FIG. 20C, pin(s) of the light-emitting device 41 are connected to a corresponding connection pad through a soldering material S (e.g. solder tin, tin-silver-copper alloy, tin-copper alloy), and pin(s) of the pixel driving chip 42 are connected to a corresponding connection pad through a soldering material S (e.g. solder tin, tin-silver-copper alloy, tin-copper alloy). The planarization layer 65 includes a plurality of second vias a2 penetrating to the second metal layer 64. The passivation layer 66 includes a plurality of third vias a3 penetrating to the planarization layer 65. A third via a3 corresponds to a second via a2 to form a through hole penetrating from the passivation layer 66 to a connection pad of the second metal layer 64.

For example, as shown in FIGS. 20B and 20C, each light-emitting device 41 includes two pins, and each pixel driving chip 42 includes six pins. The pins of each light-emitting device 41 are respectively connected to two first pads 642 through respective through holes penetrating the planarization layer 65 and the passivation layer 66. The pins of each pixel driving chip 42 are respectively connected to six second pads 643 through respective through holes penetrating the planarization layer 65 and the passivation layer 66. Thus, the light-emitting devices 41 are controlled to emit light under a control of signals transmitted from signal lines (the first signal lines 621 and/or the second signal lines 641) and the pixel driving chips 42.

As shown in FIGS. 20A and 20B, the plurality of electrodes 5 are located in the second metal layer 64, and widths (i.e., dimensions in the first direction X) of the plurality of electrodes 5 are different. Moreover, the width of each electrode 5 corresponds to a width of a signal line (as shown in FIGS. 20A and 20B, for example, a width of a second signal line 641) to which this electrode 5 is electrically connected. The electrodes 5 to which signal lines with different widths are respectively electrically connected have different widths.

In some embodiments, the first metal layer 62 or the second metal layer 64 is a metal layer including a plurality of stacked structures. For example, the first metal layer 62 or the second metal layer 64 includes a titanium layer, a copper layer and a titanium layer arranged in sequence from the side of the substrate 1. Alternatively, the first metal layer 62 or the second metal layer 64 includes, for example, a molybdenum layer, a copper layer and a molybdenum layer arranged in sequence from the side of the substrate 1. Alternatively, the first metal layer 62 or the second metal layer 64 includes, for example, a molybdenum layer, an aluminum layer and a molybdenum layer arranged in sequence from the side of the substrate 1.

In some embodiments, the first metal layer 62 or the second metal layer 64 is a signal wiring layer of a single-layer structure. Furthermore, the driving circuit layer is, for example, a copper layer or an aluminum layer.

The first metal layer 62 or the second metal layer 64 needs to have good electrical conductivity, which is only described here as an example, and is not intended to limit a material used for the driving circuit layer 6.

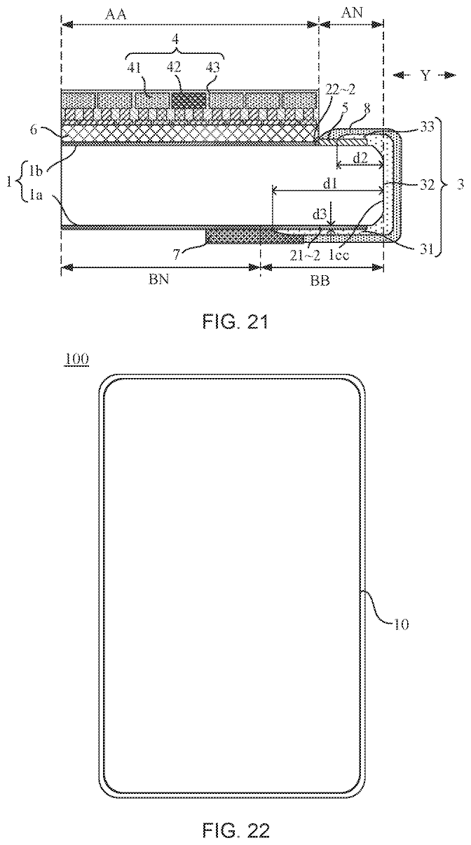

For example, as shown in FIG. 21, the display panel 10 further includes protective layer(s) 8 each disposed on a side of the connection leads 3 away from the substrate 1.

An orthographic projection of the protective layer 8 on the substrate 1 covers an orthographic projection of the connection leads 3 on the substrate 1.

In some examples, the protective layer 8 directly covers the side of the connection leads 3 away from the substrate 1. An end of the protective layer 8 is located on the first surface 1a of the substrate 1, and a middle portion of the protective layer 8 is located on the selected side surface 1cc of the substrate 1, and another end of the protective layer 8 is located on the second surface 1b of the substrate 1.

By arranging the protective layer(s) 8, the plurality of connection leads 3 are covered, so that the plurality of connection leads 3 are isolated from external air and moisture, thereby effectively avoiding abnormal transmission of signals caused by a short circuit of the plurality of connection leads 3 due to corrosion of water and oxygen.

In another aspect, the display device 100 is provided. As shown in FIG. 22, the display device 100 includes the display panel 10 in any one of the above embodiments.

Compared with traditional LEDs, mini light-emitting diodes or micro light-emitting diodes are used as the light-emitting devices 41, so that the light-emitting devices 41 occupy a smaller volume, and are smaller particles. In the same screen size, a density of light sources per unit area is higher, and a unit size of light sources is smaller. Therefore, more precise local control may be realized on the light-emitting device 41, and the problem of uneven brightness of the light-emitting device 41 does not occur, which may ensure a uniformity of display brightnesses, thereby ensuring the display quality of the display device 100.

In some embodiments, the display device 100 further includes an integrated circuit chip and the flexible printed circuit 7.

For example, as shown in FIGS. 4 to 8, the integrated circuit chip is configured to be electrically connected to the flexible printed circuit 7. The integrated circuit chip sends driving signals. Then, the driving signals are respectively transmitted to the plurality of connection leads 3 through the flexible printed circuit 7, and are respectively transmitted to the plurality of electrodes 5 through the plurality of connection leads 3. The plurality of electrodes 5 are configured to be electrically connected to the driving circuit layer 6. The driving circuit layer 6 includes, for example, a plurality of signal lines and other structures. The driving circuit layer 6 is coupled to the light-emitting device layer 4, and is configured to drive the light-emitting device layer 4 to emit light. The plurality of electrodes 5 receive respective driving signals transmitted by the plurality of connection leads 3, and transmit the respective driving signals to the driving circuit layer 6, so as to control the light-emitting device layer 4 to emit light, so that the display device 100 displays image(s).

For example, the light-emitting device layer 4 further includes the pixel driving chips 42. It will be understood that the driving circuit layer 6 may also be connected to the pixel driving chips 42, so that the pixel driving chip 42 may control brightness(es) of the light-emitting device(s) 41. The pixel driving chip 42 may drive and control three light-emitting devices 41, which is not limited herein.

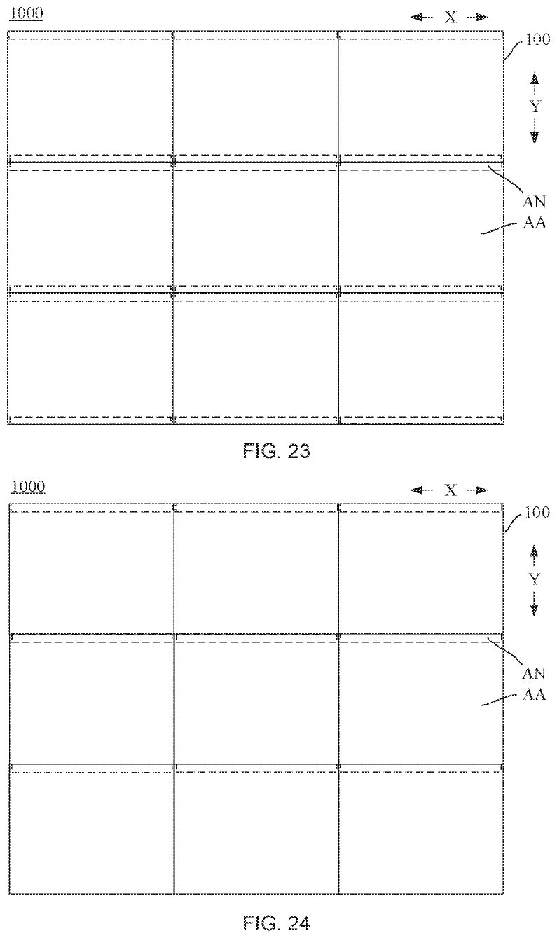

In yet another aspect, the splicing display device 1000 is provided. As shown in FIGS. 23 and 24, the splicing display device 1000 includes a plurality of display devices 100 in any one of the above embodiments.

For example, the plurality of display devices 100 in the splicing display device 1000 are arranged in an array.

For example, as shown in FIGS. 23 and 24, the display device 100 is, for example, rectangular.

In the display panel 10, the electrodes 5 are arranged side by side in the first direction X. Accordingly, the connection leads 3 are also arranged side by side in the first direction X. Another direction that is parallel to a display surface of the display device 100 and perpendicular to the first direction X is referred to as a second direction Y. The display device 100 includes a plurality of side surfaces. Hereinafter, a side surface in the plurality of side surfaces of the display device 100 proximate to the peripheral region AN of the substrate 1 is referred to as a selected side surface of the display device 100 for description.

For example, as shown in FIG. 2A, the substrate 1 has the display region AA and two peripheral regions AN respectively located on two opposite sides of the display region AA. The plurality of connection leads 3 are equally divided into two groups arranged respectively next to the two peripheral regions AN of the substrate 1, and the plurality of electrodes 5 are equally divided into two groups arranged respectively next to the two peripheral regions AN of the substrate 1.

Furthermore, as shown in FIG. 23, when the plurality of display devices 100 each including the display panel 10 shown in FIG. 2A are spliced, selected side surfaces of two adjacent display devices 100 are arranged in the first direction X. In this way, in display devices 100 arranged in a row in the first direction X, two adjacent display devices 100 basically have no splicing seam therebetween in the first direction X. In display devices 100 arranged in a column in the second direction Y, two adjacent display devices 100 have a splicing seam therebetween. That is, a dimension of a splicing seam between two adjacent display devices in the display devices 100 arranged in the row in the first direction X is less than a dimension of the splicing seam between two adjacent display devices 100 in the display devices 100 arranged in the column in the second direction Y.

However, a dimension of the peripheral region AN in the second direction Y is very small, so that when the splicing display device 1000 is actually viewed, the splicing seam between two adjacent display devices 100 is difficult to be found by naked eyes within a viewing distance. Thus, a display picture of the splicing display device 1000 is complete, and may exhibit a good display effect.

For example, as shown in FIG. 2B, the substrate 1 has the display region AA and a single peripheral region AN located on a side of the display region AA. The plurality of connection leads 3 and the plurality of electrodes 5 are arranged next to the peripheral region AN of the substrate 1.

Furthermore, as shown in FIG. 24, when the plurality of display devices 100 each including the display panel 10 shown in FIG. 2B are spliced, selected side surfaces of two adjacent display devices 100 are arranged in the first direction X. In this way, in display devices 100 arranged in a row in the first direction X, two adjacent display devices 100 basically have no splicing seam therebetween in the first direction X. In display devices 100 arranged in a column in the second direction Y, two adjacent display devices 100 have a splicing seam therebetween. That is, a dimension of a splicing seam between two adjacent display devices in the display devices 100 arranged in the row in the first direction X is less than a dimension of the splicing seam between two adjacent display devices 100 in the display devices 100 arranged in the column in the second direction Y.

However, the dimension of the peripheral region AN in the second direction Y is very small, so that when the splicing display device 1000 is actually viewed, the splicing seam between two adjacent display devices 100 is difficult to be found by naked eyes within a viewing distance. Thus, the display picture of the splicing display device 1000 is complete, and may exhibit a good display effect.

In yet another aspect, a manufacturing method of a display panel 10 is provided.

The manufacturing method of the display panel 10, as shown in FIG. 15, includes following steps.

In S1, an initial substrate 1′ is provided.

The initial substrate 1′ includes a first surface 1′a and a second surface 1′b opposite to each other.

The initial substrate 1′ includes a plurality of substrate partitions F arranged in an array.

In S2, a plurality of light-blocking layers 2 arranged in an array are formed on the initial substrate 1′.

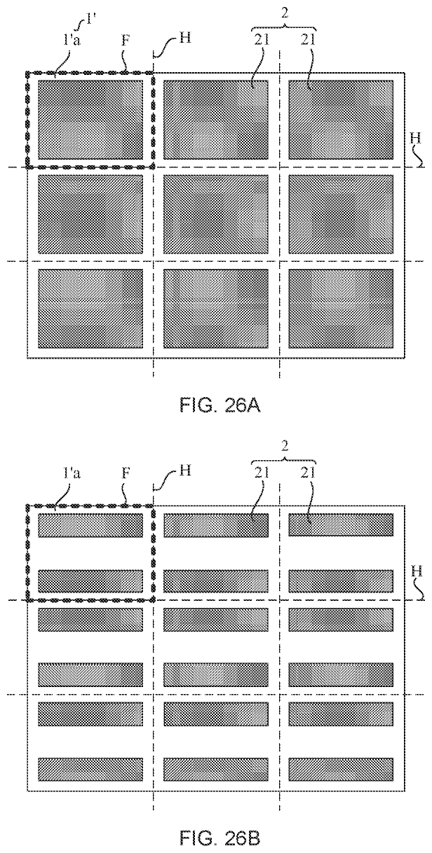

As shown in FIGS. 26A and 26B, forming the plurality of light-blocking layers 2 arranged in the array on the initial substrate 1′ includes: at least forming a plurality of first light-blocking layers 2 on the first surface 1′a of the initial substrate 1′. Two adjacent first light-blocking layers 21 have an interval therebetween, and each substrate partition F includes at least one first light-blocking layer 21.

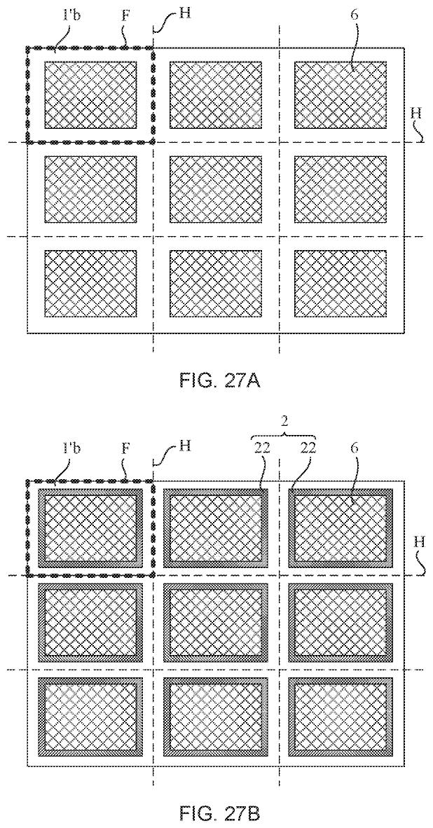

In S3, as shown in FIGS. 27A and 27B, a plurality of driving circuit layers 6 arranged in an array are formed on the second surface 1′b of the initial substrate 1′. Each substrate partition F includes a driving circuit layer 6.

In S4, the initial substrate 1′ is cut to obtain a plurality of substrates 1.

Each substrate 1 is provided with a driving circuit layer 6 and at least one first light-blocking layer 21 thereon. The substrate 1 includes a first surface 1a and a second surface 1b opposite to each other, and a plurality of side surfaces 1c connecting the first surface 1a and the second surface 1b. Each of at least one of the plurality of side surfaces 1c is a selected side surface 1cc. The first surface 1a of the substrate 1 and the first surface 1′a of the initial substrate 1′ are in the same plane.

In S5, a plurality of connection leads 3 are formed on a side of the light-blocking layer 2 away from the substrate 1.

Each of the plurality of connection leads 3 includes a first portion 31 located on the first surface 1a of the substrate 1, a second portion 32 located on the selected side surface 1cc of the substrate 1, and a third portion 33 located on the second surface 1b of the substrate 1. The first light-blocking layer 21 is located between the first portions 31 of the connection leads 3 and the substrate 1.

In S6, a light-emitting device layer 4 is formed on a side of the driving circuit layer 6 away from the substrate 1.

Since the substrate 1 is cut from the initial substrate 1′, it will be understood that the first surface 1a of the substrate 1 and the first surface 1′a of the initial substrate 1′ are in the same plane. The plurality of first light-blocking layers 21 formed on the first surface 1′a of the initial substrate 1′ are also located on the first surface 1a of the substrate 1. The driving circuit layer 6 formed on the second surface 1′b of the initial substrate 1′ is also located on the second surface 1b of the substrate 1. Hereinafter, a side of the substrate 1 provided with the light-emitting device layer 4, i.e., the second surface 1b of the substrate 1, is referred to as a front of the substrate 1, and the first surface 1a of the substrate 1 is referred to as a back surface of the substrate 1. Accordingly, initially The second surface 1′b of the initial substrate 1′ is a front of the initial substrate 1′, and the first surface 1′a of the initial substrate 1′ is a back of the initial substrate 1′.

In S5, the plurality of connection leads 3 are formed on the side of the light-blocking layer 2 away from the substrate 1. For example, firstly, metal layer(s), each of which is a whole layer, are respectively formed on the selected side surface(s) 1cc of the substrate 1 by a three-dimensional sputtering coating process. Then, the metal layer(s) are trimmed by a laser process, so that the metal layer(s) are patterned to form the plurality of connection leads 3, and a wiring (e.g. the connection lead 3) on the front of the substrate 1 detours to the back of the substrate 1 via the selected side surface 1cc. It is necessary to reserve a space for wirings on the back for external wiring bonding (for example, a portion, away from the selected side surface 1cc of the substrate 1, of the first portion 31 of each of the plurality of connection leads 3 is configured to be electrically connected to a flexible printed circuit and/or a driving chip). Therefore, the back requires longer line lengths by laser etching. That is, the first portions 31 of the plurality of connection leads 3 located on the first surface 1a of the substrate 1, are longer than third portions 33 of the plurality of connection leads 3 located on the second surface 1b of substrate 1.

That is, in an etching process of the back, the laser is irradiated into the front display region AA. As shown in FIG. 1, the laser is irradiated to the substrate 1 in the Laser direction shown in the figure. The first portions of the plurality of connection leads 3 located on the first surface 1a of the substrate 1 have the length of d1, and the third portions of the plurality of connection leads located on the second surface 1b of the substrate 1 have the length of d2, and d1 is greater than d2. Therefore, the laser emitted from the first surface 1a (back) of the substrate 1 is irradiated into the display region AA, so that residual energy causes damage to the film layers in the display region AA, and even affects the characteristics of the light-emitting devices, thereby resulting in quality problems of a product, such as localized corrosion, reliability NG, unable to light up.

The above manufacturing processes, such as the sputtering coating process and the laser process, are only described as examples, and are not intended to limit the actual production process.

By adding S2, when S5 is performed, the first light-blocking layer(s) 21 are formed between the region covered by the first portions 31 of the plurality of connection leads 3 and the substrate 1. Therefore, when the laser process is used, the laser is able to be effectively prevented from passing through the substrate 1, so as to be prevented from being irradiated to the film layer structures on the front of the substrate 1.

In some embodiments, in S2, the light-blocking layer 2 is manufactured by using a plasma enhanced chemical vapor deposition (PECVD) method. In this way, by controlling conditions such as deposition temperature, materials with different optical properties may be produced, thereby ensuring that the properties of the manufactured light-blocking layer 2 are able to meet requirements.

In some other embodiments, in S2, the light-blocking layer 2 is manufactured by masking and printing.

In some examples, as shown in FIGS. 26A and 26B, the first light-blocking layer 21 is a film layer of an integral structure.

In some other examples, as shown in FIG. 17, the first light-blocking layer 21 includes a plurality of first light-blocking patterns 211 arranged side by side in the first direction X, and two adjacent first light-blocking patterns 211 have a certain interval therebetween. That is, the first light-blocking layer 21 includes the plurality of first light-blocking patterns 211 spaced apart from each other. Furthermore, connection leads 3 are arranged side by side in the first direction X, and the first portion 31 of each connection lead 3 extends in the second direction Y. Each first light-blocking pattern 211 is located between first portions 31 of two adjacent connection leads. In the first direction X, a dimension d4 of the first light-blocking pattern 211 is greater than a distance d6 between two adjacent first portions 31.

In this case, a mask is firstly placed on the first surface 1a of the substrate 1, hollows of the mask respectively correspond to the plurality of first light-blocking patterns 211. Then, the plurality of first light-blocking patterns 211 are formed by using a printing process.

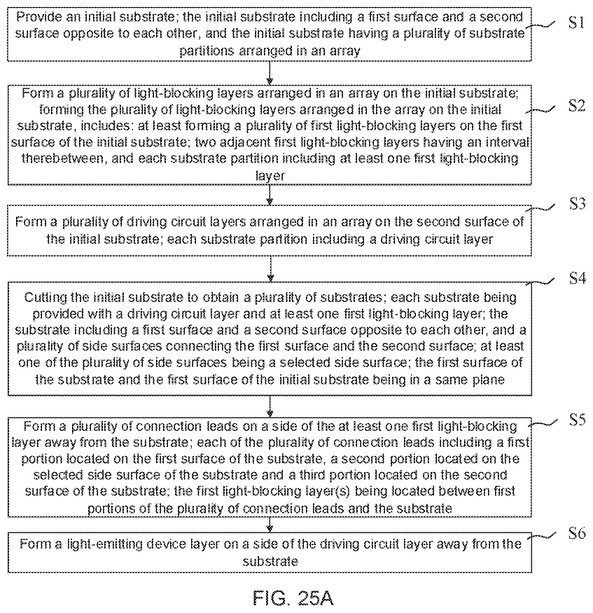

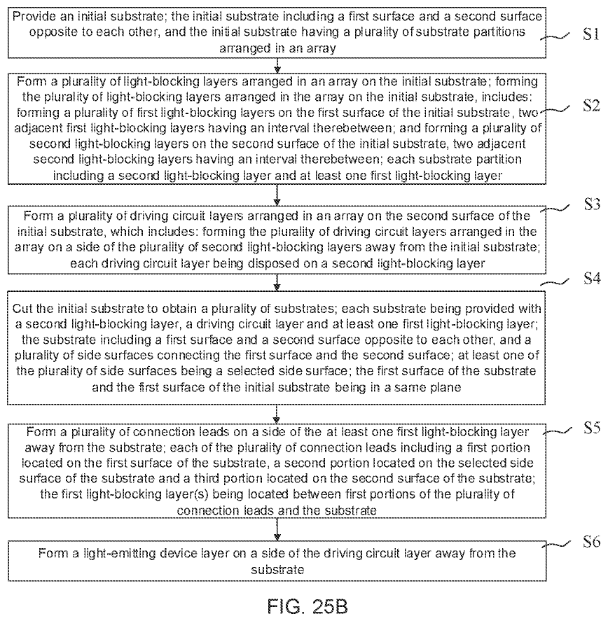

For example, as shown in FIG. 25B, in S2, the plurality of light-blocking layers 2 are formed on the initial substrate 1′. A plurality of second light-blocking layers 22 are formed on the second surface 1′b of the initial substrate 1′. The initial substrate 1′ has the plurality of substrate partitions F, and is cut along boundaries of the substrate partitions F to obtain a substrate 1. The plurality of second light-blocking layers 22 are arranged in the same layer, and different second light-blocking layers 22 are located in different substrate partitions F. Two adjacent second light-blocking layers 22 have an interval therebetween, each substrate partition F includes a second light-blocking layer 22.

In S3, the plurality of driving circuit layers 6 are formed on the second surface 1′b of the initial substrate 1′. The plurality of driving circuit layers 6 are formed on a side of the second light-blocking layers 22 away from the initial substrate 1′, and each driving circuit layer 6 is disposed on a second light-blocking layer 22. The plurality of first light-blocking layers 21 are arranged in the same layer, and different first light-blocking layers 21 are located in different substrate partitions F. The plurality of second light-blocking layers 22 are arranged in the same layer, and different second light-blocking layers 22 are located in different substrate partitions F. That is, a single substrate partition F may include a single first light-blocking layer 21 and/or a single second light-blocking layer 22.

In S4, the initial substrate 1′ is cut along the boundaries of the substrate partition F to obtain the plurality of substrates 1. Each substrate 1 is further provided with a second light-blocking layer 22.

In S2, the plurality of light-blocking layers 2 arranged in the array are formed on the initial substrate 1′. Forming the light-blocking layer 2 includes: forming the plurality of first light-blocking layers arranged in the array on the first surface 1′a of the initial substrate 1′; and/or forming the plurality of second light-blocking layers 22 arranged in an array on the second surface 1′b of the initial substrate 1′.

In some embodiments, in S2, the plurality of light-blocking layers 2 arranged in the array are directly formed on the surface of the initial substrate 1′.

The plurality of light-blocking layers 2 may be arranged next to the initial substrate 1′. That is, in the substrate 1 obtained by cutting the initial substrate 1′ with the light-blocking layers 2 and the driving circuit layers 6, the first light-blocking layer 21 is arranged next to the first surface 1a of the substrate 1, and/or the second light-blocking layer 22 is arranged next to the second surface 1b of the substrate 1.

In some other embodiments, other film structure(s) such as buffer layer(s) are formed on the surface (the first surface 1′a and/or the second surface 1′b) of the initial substrate 1′ in S1. Then, in S2, the light-blocking layer 2 is formed on a side of the formed other film structure(s) away from the initial substrate 1′.

For example, before S2, a first buffer layer is formed on the first surface 1′a of the initial substrate 1′, and the plurality of first light-blocking layers 21 formed in S2 are formed on a side of the first buffer layer away from the initial substrate 1′; and/or

before S2, a second buffer layer is formed on the second surface 1′b of the initial substrate 1′, and the plurality of second light-blocking layers 22 formed in S2 are formed on a side of the second buffer layer away from the initial substrate 1′.

It will be noted that the other film layer structure(s) such as the buffer layer(s) formed on the surface (the first surface 1′a and/or the second surface 1′b) of the initial substrate 1′ in S1 are not used for transmitting signals, and do not participate in circuit connections. Therefore, in the manufacturing process of the display panel 10, the film layer structure(s) are damaged by the laser, which does not affect the normal operation of the display panel 10.

As shown in FIGS. 25A, 25B, 26A and 26B, in the plurality of light-blocking layers 2 arranged in the array formed in S2, for example, in the first light-blocking layers 21 and the second light-blocking layers 22, there is a set distance between two adjacent light-blocking layers 2. Therefore, in the plurality of substrates 1 obtained by cutting the initial substrate 1′ in S4, as shown in FIGS. 9, 10 and 14, There is also a certain distance between the light-blocking layer 2 included in each substrate 1 and a border (the border here refers to a border of the first surface 1a and/or a border of the second surface 1b of the substrate 1) of the substrate 1. That is, borders of the light-blocking layer 2 on the surface of the substrate 1 are surrounded by the borders of the surface of the substrate 1, and an area of the light-blocking layer 2 is less than an area of the surface of the substrate 1, so that a position of the light-blocking layer 2 on the substrate 1, and an adhesion degree between the light-blocking layer 2 and the substrate 1 may be ensured. It will be understood that by using such design, following problems are able to be effectively avoided. In the manufacturing process of the remaining components of the display panel 10, for example, in S4, along the cutting line H shown in FIGS. 25A, 25B, 26A and 26B, the initial substrate 1′ is cut into the plurality of substrates 1, if there is no interval between the plurality of light-blocking layers 2 on the surface of the initial substrate 1′, when the initial substrate 1′ is cut along the cutting line H, an edge of the light-blocking layer is scratched, which results in defects such as burrs and edge chipping on the edge of the light-blocking layer 2. Thus, the edge of the light-blocking layer 2 is peeled from the substrate 1, which results in poor adhesion, so that a portion of the substrate 1 should be covered by the light-blocking layer 2 is exposed. In this case, the laser passes through the peeled portion of the light-blocking layer 2 to be irradiated to the film layer structures on the front of the display panel 10, so that the light-blocking layer 2 does not have the desired effect.

For example, the first surface 1a of the substrate 1 has a display region AA and peripheral region(s) AN respectively located on at least one side of the display region AA. The second surface 1b of the substrate 1 has wiring region(s) BB and a non-wiring region BN. The wiring region BB is closer to the selected side surface 1cc of the substrate 1 than the non-wiring region BN. The first portions 31 of the plurality of connection leads 3 are located in the wiring region(s) BB, and the third portions 33 of the plurality of connection leads 3 are located in the peripheral region(s) AN.

In some embodiments, as shown in FIGS. 9 and 26A, the first light-blocking layer 21 formed on the first surface 1a of the substrate 1 is disposed in the wiring region(s) BB and the non-wiring region BN. It will be understood that the first light-blocking layer 21 here is a whole film layer, and there is a set distance between a border of the first light-blocking layer 21 and a corresponding border of the first surface 1a of the substrate 1. That is, the borders of the first light-blocking layer 21 are surrounded by the borders of the first surface 1a of the substrate 1.

In some other embodiments, as shown in FIGS. 10 and 26B, the first light-blocking layer 21 formed on the first surface 1a of the substrate 1 is disposed in the wiring region BB. In a case where the substrate 1 includes, for example, a single selected side surface 1cc, the substrate 1 has a single wiring region BB, and the first light-blocking layer 21 is located in this wiring region BB. In a case where the substrate includes, for example, two opposite selected side surfaces 1cc, the substrate 1 has two wiring regions BB. Accordingly, the first light-blocking layers 21 are respectively located in the two wiring regions BB. It will be understood that there are two first light-blocking layers 21, and a border of each of the first light-blocking layers 21 and a corresponding border of the substrate 1 have a set distance therebetween. Moreover, there is also a set distance between a border of a region covered by an entirety of the two first light-blocking layers 21 and a corresponding border of the first surface 1a of the substrate 1. That is, the borders of the region covered by the first light-blocking layers 21 are surrounded by the borders of the first surface 1a of the substrate 1.

In some embodiments, as shown in FIGS. 14 and 27B, the second light-blocking layer 22 formed on the second surface 1b of the substrate 1 is disposed in the display region AA, and an orthographic projection of the second light-blocking layer 22 on the second surface 1b of the substrate 1 covers the display region AA. That is, borders of the display region AA are surrounded by borders of the second light-blocking layer 22.

By forming the second light-blocking layer 22 on the second surface 1b of the substrate 1, the film layer structures on the second surface 1b may be better protected. Moreover, compared with the case that the second light-blocking layer 22 is formed in the display region AA, the coverage of the second light-blocking layer 22 is slightly expanded compared with the display region AA, which is able to better protect the film layers in the display region AA.

In some examples, as shown in FIGS. 26A and 26B, the plurality of light-blocking layers 2 arranged in the array formed on the initial substrate 1′ include the first light-blocking layers 21 and/or the second light-blocking layers 22, and each light-blocking layer 2 is a film layer of an integral structure. The dimension d3 of the light-blocking layer 2 in the direction perpendicular to the substrate 1 is greater than or equal to 0.3 μm. The dimension d3 of the light-blocking layer 2 in the direction perpendicular to the substrate 1 is, for example, 0.3 μm, 0.4 μm or 0.5 μm. In some other examples, as shown in FIG. 17, the plurality of light-blocking layers 2 arranged in the array formed on the initial substrate 1′ include the first light-blocking layers 21, and each first light-blocking layer 21 includes the plurality of first light-blocking patterns 211. The dimension d3 of each first light-blocking pattern 211 in the direction perpendicular to the substrate 1 is greater than or equal to 0.03 μm. The dimension d3 of the first light-blocking pattern 211 in the direction perpendicular to the substrate 1 is, for example, 0.03 μm, 0.04 μm or 0.05 μm.

Under the premise of not affecting the stress of the light-blocking layer 2, the thickness of the light-blocking layer 2 may be appropriately increased. On one hand, due to the increased thickness of the light-blocking layer 2, the light-blocking layer 2 is capable of better blocking the laser penetration, so that the extinction ability of the light-blocking layer 2 is enhanced to weaken the laser. On another hand, the light-blocking layer 2 may further be used as the sacrificial layer. In this way, even if the light-blocking layer 2 is damaged in the laser etching process or other processes, which results in a reduction in thickness of the light-blocking layer 2, the light-blocking layer 2 may still maintain a certain thickness, and is still capable of preventing the laser from entering the display region AA on the front of the display panel 10, thereby preventing the film layers on the front of the display panel 10 from being damaged by the laser.

After the plurality of connection leads 3 are formed on the side of the light-blocking layer 2 away from the substrate 1 in S3, and before the light-emitting device layer 4 is formed on the second surface 1b of the substrate 1 in S4, S3-1 is further included, i.e., protective layer(s) 8 are formed on a side of the plurality of connection leads 3 away from the substrate 1. The protective layer(s) 8 cover the plurality of connection leads 3.

In S3-1, the protective layer(s) 8 are formed to cover the side of the plurality of connection leads 3 away from the substrate 1. An end of the protective layer 8 is located on the first surface 1a of the substrate 1, and a middle portion of the protective layer 8 is located on the selected side surface 1cc of the substrate 1, and another end of the protective layer 8 is located on the second surface 1b of the substrate 1.

By arranging the protective layer(s) 8, the plurality of connection leads 3 are covered, so that the plurality of connection leads 3 are isolated from external air and moisture, thereby effectively avoiding abnormal transmission of signals caused by a short circuit of the plurality of connection leads 3 due to corrosion of water and oxygen.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate; wherein the substrate includes a first surface and a second surface opposite to each other, and a plurality of side surfaces connecting the first surface and the second surface; at least one of the plurality of side surfaces is a selected side surface;
a light-emitting device layer disposed on the second surface of the substrate;
a plurality of connection leads; wherein each of the plurality of connection leads includes a first portion located on the first surface, a second portion located on the selected side surface and a third portion located on the second surface; and
a light-blocking layer; wherein the light-blocking layer is located between the plurality of connection leads and the substrate, and is at least located between first portions of the plurality of connection leads and the first surface of the substrate.

2. The display panel according to claim 1, wherein the light-blocking layer includes a first light-blocking layer disposed on the first surface of the substrate;
the first surface of the substrate has a wiring region and a non-wiring region, and the wiring region is closer to the selected side surface than the non-wiring region; the first portions of the plurality of connection leads are located in the wiring region;
the first surface includes a plurality of sides; wherein
the first light-blocking layer is located in the wiring region and the non-wiring region of the first surface, and a border of an orthographic projection of the first light-blocking layer on the first surface and a corresponding side of the first surface have a set distance therebetween; or
the first light-blocking layer is located in the wiring region of the first surface, and a border of the orthographic projection of the first light-blocking layer on the first surface and a corresponding side of the first surface have a set distance therebetween.

3. The display panel according to claim 2, wherein the first light-blocking layer is located in the wiring region of the first surface; in the first portions of the plurality of connection leads, a region located between first portions of every two adjacent connection leads is a gap region;
the first light-blocking layer includes a plurality of first light-blocking patterns; an orthographic projection of each first light-blocking pattern in the plurality of first light-blocking patterns on the first surface covers at least a portion of an orthographic projection of the gap region on the first surface that is overlapped with an orthographic projection of the light-emitting device layer on the first surface.

4. The display panel according to claim 3, wherein a dimension of the first light-blocking pattern in a first direction perpendicular to an extending direction of the first light-blocking pattern is greater than or equal to a dimension of the gap region corresponding to the first light-blocking pattern in a direction perpendicular to an extending direction of the gap region.

5. The display panel according to claim 3, wherein the display panel further comprises a plurality of electrodes disposed on the second surface of the substrate, and each of the plurality of electrodes is connected to a third portion of a connection lead; wherein
a dimension of the first light-blocking pattern in a first direction perpendicular to an extending direction of the first light-blocking pattern is less than a distance between two adjacent electrodes to which two adjacent connection leads corresponding to the first light-blocking pattern are respectively electrically connected.

6. The display panel according to claim 2, wherein the first light-blocking layer is located in the wiring region of the first surface; and a border of the first light-blocking layer away from the selected side surface is farther from the selected side surface than borders of the plurality of connection leads away from the selected side surface.

7. The display panel according to claim 5, wherein the plurality of electrodes are arranged side by side in the first direction; and a sum of a distance between first portions of the two adjacent connection leads and a dimension of a first portion of a connection lead in the two adjacent connection leads in the first direction, is equal to a sum of the distance between the two adjacent electrodes to which the two adjacent connection leads are respectively electrically connected and a dimension of an electrode in the two adjacent electrodes in the first direction.

8. The display panel according to claim 7, wherein a difference between the distance between the two adjacent electrodes and the distance between the first portions of the two adjacent connection leads is greater than a difference between the dimension of the first portion of the connection lead in the two adjacent connection leads in the first direction and a dimension of an electrode electrically connected to this connection lead in the first direction.

9. The display panel according to claim 2, wherein the light-blocking layer further includes a second light-blocking layer disposed on the second surface of the substrate; and
the second surface of the substrate has a display region and a peripheral region disposed on a side of the display region; an orthographic projection of the second light-blocking layer on the second surface covers at least a portion, overlapped with the display region, of a region of the second surface corresponding to the wiring region; and a border of the orthographic projection of the second light-blocking layer on the second surface and a corresponding side of the second surface have a set distance therebetween.

10. The display panel according to claim 9, wherein a distance between a border, proximate to the selected side surface, of the orthographic projection of the first light-blocking layer on the first surface and the selected side surface is less than a distance between a border of the display region proximate to the selected side surface and the selected side surface.

11. The display panel according to claim 2, wherein in the plurality of sides included in the first surface, a side proximate to the selected side surface is a first selected side;
a distance between a border, proximate to a side in the plurality of sides of the first surface except the first selected side, of the orthographic projection of the first light-blocking layer on the first surface of the substrate and the side in the plurality of sides of the first surface except the first selected side, is less than a distance between a border, proximate to the first selected side, of the orthographic projection of the first light-blocking layer on the first surface and the first selected side; and/or
the light-blocking layer further includes a second light-blocking layer disposed on the second surface of the substrate;
the second surface includes a plurality of sides, and in the plurality of sides included in the second surface, a side proximate to the selected side surface is a second selected side;
a distance between a border, proximate to a side in the plurality of sides of the second surface except the second selected side, of an orthographic projection of the second light-blocking layer on the second surface of the substrate and the side in the plurality of sides of the second surface except the second selected side is less than a distance between a border, proximate to the second selected side, of the orthographic projection of the second light-blocking layer on the second surface and the second selected side.

12. The display panel according to claim 11, wherein
the distance between the border, proximate to the side in the plurality of sides of the first surface except the first selected side, of the orthographic projection of the first light-blocking layer on the first surface and the side in the plurality of sides of the first surface except the first selected side is greater than or equal to 30 μm.

13. The display panel according to claim 1, wherein a dimension of the light-blocking layer in a direction perpendicular to the substrate is greater than or equal to 0.3 μm; and/or
the light-blocking layer is made of an insulating light-shielding material.

14. (canceled)

15. The display panel according to claim 1, wherein a reflectivity of the light-blocking layer to laser is greater than a reflectivity of the plurality of connection leads to the laser.

16. The display panel according to claim 1, wherein the light-blocking layer is made of any one of silicon nitride, monocrystalline silicon, silicon oxide, fluoride and ink.

17. The display panel according to claim 1, further comprising:
a protective layer disposed on a side of the plurality of connection leads away from the substrate.

18. A display device, comprising the display panel according to claim 1.

19. A splicing display device, comprising a plurality of display devices according to claim 18.

20. A manufacturing method of a display panel, comprising:
providing an initial substrate; wherein the initial substrate includes a first surface and a second surface opposite to each other, and the initial substrate has a plurality of substrate partitions arranged in an array;
forming a plurality of light-blocking layers on the initial substrate; wherein forming the plurality of light-blocking layers on the initial substrate, includes: at least forming a plurality of first light-blocking layers on the first surface of the initial substrate; wherein two adjacent first light-blocking layers have an interval therebetween, and each substrate partition includes at least one first light-blocking layer;
forming a plurality of driving circuit layers arranged in an array on the second surface of the initial substrate; wherein each substrate partition includes a driving circuit layer;
cutting the initial substrate to obtain a plurality of substrates; wherein each substrate is provided with a driving circuit layer and at least one first light-blocking layer; the substrate includes a first surface and a second surface opposite to each other, and a plurality of side surfaces connecting the first surface and the second surface; at least one of the plurality of side surfaces is a selected side surface, and the first surface of the substrate and the first surface of the initial substrate are in a same plane;
forming a plurality of connection leads on a side of the at least one first light-blocking layer away from the substrate; wherein each of the plurality of connection leads includes a first portion located on the first surface, a second portion located on the selected side surface and a third portion located on the second surface; the at least one first light-blocking layer is located between first portions of the plurality of connection leads and the substrate; and
forming a light-emitting device layer on a side of the driving circuit layer away from the substrate.

21. The manufacturing method according to claim 20, wherein
forming the plurality of light-blocking layers on the initial substrate, further includes: forming a plurality of second light-blocking layers on the second surface of the initial substrate; wherein two adjacent second light-blocking layers have an interval therebetween, each substrate partition includes a second light-blocking layer;
forming the plurality of driving circuit layers arranged in the array on the second surface of the initial substrate, includes: forming the plurality of driving circuit layers arranged in the array on a side of the plurality of second light-blocking layers away from the initial substrate; wherein each driving circuit layer is disposed on a second light-blocking layer; and
the initial substrate is cut to obtain the plurality of substrates, so that each substrate is further provided with a second light-blocking layer.
